(19) United States
(12) Patent Application Publication
(10) Pub. No.: US 2012/0236467 A1
(43) Pub. Date: Sep. 20, 2012

(54) ULTRACAPACITOR, METHODS OF MANUFACTURING AND APPLICATIONS OF THE SAME

(75) Inventors: Weng Poo Kang, Nashville, TN (US); Supil Raina, Nashville, TN (US); SiYu Wei, Nashville, TN (US); Shao-Hua Hsu, Nashville, TN (US)

(73) Assignee: Vanderbilt University, Center for Technology Transfer and Commercialization, Nashville, TN (US)

(21) Appl. No.: 13/421,342

(22) Filed: Mar. 15, 2012

Related U.S. Application Data
(60) Provisional application No. 61/453,473, filed on Mar. 16, 2011.

(51) Int. Cl. H01G 9/155; H01G 7/00; H01L 29/02; H01L 21/02; B82Y 30/00

(52) U.S. Cl. 361/502; 257/532; 438/381; 29/25.42; 977/700; 977/742; 257/E29.002; 257/E21.008

(57) ABSTRACT

In one aspect of the present invention, an ultracapacitor has a first plate, a second plate and a separator sandwiched between the first plate and the second plate. Each of the first plate and the second plate includes a substrate, first nanostructures formed on the substrate, and second nanostructures, being different from the first nanostructures, attached to the first nanostructures. The first nanostructures include carbon nanotubes (CNTs) or carbon fibers/nanofibers (CFs). The second nanostructures include nano-particles of an active material including MnO₂.

### CROSS-REFERENCE TO RELATED PATENT APPLICATION

This application claims priority to and the benefit of, pursuant to 35 U.S.C. §119(e), U.S. provisional patent application Ser. No. 61/453,473, filed Mar. 16, 2011, entitled “ENHANCED ELECTROCHEMICAL ULTRACAPACITOR, METHODS OF MAKING AND APPLICATIONS OF THE SAME,” by Weng Poo Kang, Supil Raina and Siyu Wei, the disclosure of which is incorporated herein in its entirety by reference.

Some references, which may include patents, patent applications and various publications, are cited and discussed in the description of this invention. The citation and/or discussion of such references is provided merely to clarify the description of the present invention and is not an admission that any such reference is “prior art” to the invention described herein. All references cited and discussed in this specification are incorporated herein by reference in their entireties and to the same extent as if each reference was individually incorporated by reference.

### FIELD OF THE INVENTION

The present invention relates generally to electrochemical capacitors, and more particularly to ultracapacitors that utilize a hybrid of carbon nanotubes and nanoparticles of an active material as electrodes, and methods of manufacturing and applications of the same.

### BACKGROUND OF THE INVENTION

Ultracapacitors, also known as supercapacitors, are electrochemical capacitors with relatively high energy density. Generally, an ultracapacitor has the energy density which is hundreds of times greater than that of a conventional electrolytic capacitor. Carbon nanotube (CNT) forests perform well as ultracapacitor electrodes because of their high electrical conductivity, large surface area, polarizability, and chemical and thermal stability. Despite these advantages, the specific capacitance of pristine-CNT ultracapacitors is mediocre (<40 F/g, where F/g refers to the specific capacitance of the electrode material). Methods to improve the CNT capacitance via mixing with pseudocapacitive materials have been reported.

Therefore, a heretofore unaddressed need exists in the art to address the aforementioned deficiencies and inadequacies.

### SUMMARY OF THE INVENTION

In one aspect, the present invention relates to an ultracapacitor. In one embodiment, the ultracapacitor has a first plate, a second plate and a separator sandwiched between the first plate and the second plate. Each of the first plate and second plate includes a substrate, first nanostructures formed on the substrate, and second nanostructures, being different from the first nanostructures, attached to the first nanostructures. In one embodiment, the separator is porous. The first plate and the second plate are adapted to be symmetrically or asymmetrically arranged.

The substrate can be a rigid conducting substrate or a flexible conducting substrate. In one embodiment, the substrate comprises a doped silicon substrate.

In one embodiment, the first nanostructures are grown vertically on the substrate. In one embodiment, the first nanostructures comprise carbon nanotubes (CNTs) or carbon fibers/nanofibers (CFs). The CNTs or CFs have diameters or thicknesses in a range of about 1.0-1,000.0 nm.

In one embodiment, the first nanostructures are grown in a continuous film on the entire substrate or over the region of interest of the substrate. In another embodiment, the first nanostructures are grown in a pre-determined array pattern on the substrate.

In one embodiment, the second nanostructures comprise nano-particles of an active material, having diameters or sizes in a range of about 1.0-1000.0 nm, wherein the active material comprises MnO₂, Ag₂O, FeS, RuO₂, NiOₓ, CoOₓ, V₂O₅ or a mixture thereof.

In one embodiment, the ultracapacitor also includes an electrolyte solution filled in spaces among the first nanostructures and the second nanostructures in the first plate and the second plate.

In one embodiment, the ultracapacitor further has one or more insulation layers disposed on at least one of the first plate and the second plate, such that rolling over the ultracapacitor defines a cylindrical-type multi-layered ultracapacitor cell.

In another aspect, the present invention relates to an electrical energy storage device comprising at least one ultracapacitor claimed above, where the first plate and the second plate are formed with materials and with dimensions such that the specific capacitance is greater than 500 F/g.

In yet another aspect, the present invention relates to an ultracapacitor cell having a plurality of ultracapacitors electrically parallel-connected to each other. Each ultracapacitor comprises a first plate, a second plate and a separator sandwiched between the first plate and the second plate. Each of the first plate and second plate includes a substrate, first nanostructures formed on the substrate, and second nanostructures, being different from the first nano structures, attached to the first nano structures. In one embodiment, the separator is porous.

In one embodiment, the first nanostructures comprise carbon nanotubes (CNTs) or carbon fibers/nanofibers (CFs), wherein the CNTs or CFs are grown on the substrate. In one embodiment, the first nanostructures are grown in a continuous film on the entire substrate or over the region of interest of the substrate. In another embodiment, the first nanostructures are grown in a pre-determined array pattern on the substrate.

In one embodiment, the second nanostructures comprise nano-particles of an active material, where the active material comprises MnO₂, Ag₂O, FeS, RuO₂, NiOₓ, CoOₓ, V₂O₅ or a mixture thereof.

The ultracapacitor cell may further include a first conducting track member and a second conducting track member positioned apart from the first conducting track member to define a space therebetween, such that the plurality of ultracapacitors is stacked in the space and parallel-connected through the first and second conducting track members.

Additionally, the ultracapacitor cell may also have an electrolyte solution filled in spaces among the first nanostructures and the second nanostructures in the first plate and the second plate.

In a further aspect, the present invention relates to an ultracapacitor cell. In one embodiment, the ultracapacitor cell has a first conducting track member and a second conducting track member positioned apart from the first conducting track member to define a space therebetween.

The ultracapacitor cell also has a plurality of first plates electrically coupled to the first conducting track member, and a plurality of second plates electrically coupled to the second conducting track member. The plurality of first plates and the plurality of second plates are alternately positioned in the space defined between the first conducting track member and the second conducting track member. Each of the plurality of first plates and the plurality of second plates comprises a conducting substrate, first nanostructures formed on the conducting substrate, and second nanostructures, being different from the first nanostructures, attached to the first nanostructures formed on the conducting substrate.

In one embodiment, the first nanostructures comprise carbon nanotubes (CNTs) or carbon fibers/nanofibers (CFs), where the CNTs or CFs are grown on the substrate. The second nanostructures comprise nano-particles of an active material.

Additionally, the ultracapacitor cell further includes a plurality of separators, where each separator is sandwiched between a respective first plate and its adjacent second plate in the space. In one embodiment, each separator is porous.

In yet a further aspect, the present invention relates to a method of fabricating an ultracapacitor. In one embodiment, the method has the steps of forming a first plate and a second plate, where each of the first and second plates comprises a substrate, first nanostructures formed on the substrate, and second nanostructures, being different from the first nanostructures, attached to the first nanostructures, and disposing a separator between the first plate and the second plate. In one embodiment, the separator is porous. The substrate comprises a rigid conducting substrate or a flexible conducting substrate.

In one embodiment, the step of forming each of the first plate and the second plate comprises the steps of growing vertically the first nanostructures on the substrate, and attaching the second nanostructures to the first nanostructures grown on the substrate.

The first nanostructures in one embodiment comprise carbon nanotubes (CNTs) or carbon fibers (CFs).

In one embodiment, the first nanostructures are grown in a continuous film on the entire substrate or over the region of interest of the substrate. In another embodiment, the first nanostructures are grown in a pre-determined array pattern on the substrate.

In one embodiment, the substrate is a doped n-type silicon substrate. The growing step includes the steps of oxidizing the silicon substrate to form a layer of SiO₂ on the silicon substrate, spin-coating a layer of photoresist on the SiO₂ layer, patterning the photoresist layer to expose regions of the SiO₂ layer in accordance with the pre-determined array pattern, wet-etching back of the exposed regions of the SiO₂ layer to expose the corresponding regions of the silicon substrate, depositing a buffer layer in the corresponding exposed regions of the silicon layer, lifting off the photoresist on the SiO₂ layer, and growing vertically aligned CNTs or CFs in the regions at which the buffer layer are present so as to form the array of the vertically aligned CNTs or CFs on the substrate in accordance with the pre-determined array pattern. In one embodiment, the buffer layer comprises titanium and a catalyst of cobalt.

In one embodiment, the growing step is performed with an MPECVD (microwave plasma enhanced chemical vapor deposition) process or a HFCVD (hot filament chemical vapor deposition) process or a thermal chemical vapor deposition process.

In one embodiment, the second nanostructures comprise nano-particles of an active material, and wherein the active material comprises MnO₂.

In one embodiment, the attaching step comprises the steps of preparing a suspension of the nano-particles of the active material in a liquid medium, dripping the suspension into the first nanostructures grown on the substrate, and drying the suspension to attach the nano-particles of the active material onto the first nanostructures. The liquid medium comprises acetone or water or other liquid media.

In another embodiment, the attaching step comprises the steps of providing a solution containing potassium permanganate (KMnO₄) and water, and performing in-situ electrodeposition of the solution in the CNTs or CFs grown on the substrate so as to impregnate MnO₂ directly on the CNTs or CFs.

In one embodiment, the method may also have the step of filling an electrolyte solution in spaces among the first nanostructures and the second nanostructures in the first plate and the second plate.

These and other aspects of the present invention will become apparent from the following description of the preferred embodiment taken in conjunction with the following drawings, although variations and modifications therein may be affected without departing from the spirit and scope of the novel concepts of the disclosure.

### BRIEF DESCRIPTION OF THE DRAWINGS

The accompanying drawings illustrate one or more embodiments of the invention and together with the written description, serve to explain the principles of the invention. Wherever possible, the same reference numbers are used throughout the drawings to refer to the same or like elements of an embodiment.

FIG. 1A shows schematically a cross-sectional view of a symmetric ultracapacitor according to one embodiment of the present invention.

FIG. 1B shows a scanning electron microscope (SEM) image of CNTs grown on a substrate according to one embodiment of the present invention.

FIG. 1C shows an SEM image of MnO₂ coated CNTs grown on a substrate according to one embodiment of the present invention.

FIG. 2A shows schematically a perspective view of an asymmetric or symmetric ultracapacitor with a cylindrical shape according to one embodiment of the present invention.

FIG. 2B shows schematically a perspective view of the internal structure of the asymmetric or symmetric ultracapacitor of FIG. 2A.

FIG. 2C shows schematically a top view of the internal structure of the asymmetric or symmetric ultracapacitor of FIG. 2B.

FIG. 3A shows schematically a cross-sectional view of an asymmetric or symmetric ultracapacitor with a rolled multi-stack structure according to one embodiment of the present invention.

FIG. 3B shows schematically a partial cross-sectional view of an asymmetric or symmetric ultracapacitor with a multi-stack structure according to one embodiment of the present invention.

FIG. 4A shows schematically a perspective view of an ultracapacitor with a rectangular shape according to one embodiment of the present invention.

FIG. 4B shows schematically a top view of the internal structure of the ultracapacitor of FIG. 4A.

FIG. 5A shows schematically a cross-sectional view of an ultracapacitor with a disk shape according to one embodiment of the present invention.

FIG. 5B shows schematically an explosive view of the internal structure of the ultracapacitor of FIG. 5A.

FIG. 5C shows schematically a cross-sectional view of an application of the ultracapacitor of FIG. 5A.

FIGS. 6A-6F shows schematically a process of forming a patterned CNT, CF array on a substrate according to one embodiment of the present invention.

FIG. 7A shows schematically a dripping process of coating an active material, such as MnO₂ onto CNTs or CFs grown on a substrate according to one embodiment of the present invention.

FIGS. 7B and 7C show MnO₂ coated CNTs or CFs with different drops of MnO₂ suspension according to embodiments of the present invention.

FIG. 7D shows a transmission electron microscope (TEM) image showing a CNT or CF and MnO₂ nanoparticles coated thereon according to one embodiment of the present invention.

FIG. 8 shows schematically a device of forming MnO₂ coated CNTs or CFs by electrodeposition according to one embodiment of the present invention.

FIG. 9A shows a micropatterned array of CNT/MnO₂ ultracapacitor cells according to one embodiment of the present invention.

FIG. 9B shows a micropatterned array of CNT/MnO₂ ultracapacitor cells according to another embodiment of the present invention.

FIG. 9C shows a micropatterned array of CNTs before coating of MnO₂ according to one embodiment of the present invention.

FIG. 9D shows a micropatterned array of CNTs coated with MnO₂ according to one embodiment of the present invention

FIG. 9E shows schematically a MEMS application of a micropatterned array of CNT/MnO₂ ultracapacitor cells according to another embodiment of the present invention.

FIG. 10 shows an X-ray photoelectron spectrum (XPS) of MnO₂ coated CNTs grown on a substrate according to one embodiment of the present invention.

FIG. 11 shows another XPS spectrum of MnO₂ coated CNT grown on a substrate according to one embodiment of the present invention, in which peaks at 653.6 eV (Mn 2p_{1/2}) and 642.2 eV (Mn 2p_{3/2}) correspond to MnO₂ binding energies.

FIG. 12 shows a diagram of cyclic voltammograms (CVs) of CNT and CNT coated with 15 and 30 droplets of MnO₂ according to one embodiment of the present invention.

FIG. 13 shows a plurality of diagrams of a galvano-static charging and discharging behavior of (A) as-grown CNT film at 30 μA, (B) 5-droplet sample at 30 μA, (C) 15-droplet sample at 30 μA, (D) 15-droplet sample at 120 μA, (E) 30-droplet sample at 120 μA, and (F) 30-droplet sample at 1920 μA, respectively according to one embodiment of the present invention.

FIG. 14 shows a diagram of CVs recorded during 10 cycles (20 sweep segments) of MnO₂ deposition at 100 mV/s scan rate in 10 mM KMnO₄ and potential scan limits of −1V to +1V according to a first embodiment of the present invention.

FIG. 15A shows an SEM image of as-gown CNT array according to one embodiment of the present invention.

FIG. 15B shows an SEM image a final array structure after MnO₂ deposition according to one embodiment of the present invention.

FIG. 16A shows a diagram of CVs recorded in 0.1M KCl at 100 mV/s showing the extremely high enhancement in the capacitive currents according to the first embodiment of the present invention.

FIG. 16B shows a diagram of CVs recorded in 0.1M KCl at 50 mV/s showing the extremely high enhancement in the capacitive currents according to the first embodiment of the present invention.

FIG. 16C shows diagrams of CVs for the device in 0.1M KCl before (on the left) and after MnO₂ deposition (on the right) expressed in terms of current density, volumetric current density, areal capacitance and volumetric capacitance according to the first embodiment of the present invention.

FIG. 17A shows a diagram of CVs recorded in 0.1M KCl at 100 mV/s showing almost 2× enhancement in the capacitive currents after baking at 100° C. for 1 hour according to the first embodiment of the present invention.

FIG. 17B shows a diagram of CVs recorded in 0.1M KCl at 50 mV/s showing almost 1.4× enhancement in the capacitive currents after baking at 100° C. for about 1 hour according to the first embodiment of the present invention.

FIG. 18 shows a diagram of CVs recorded during 30 cycles (60 sweep segments) of MnO₂ deposition at 100 mV/s in 10 mM KMnO₄ and potential scan limits of −1V to +1V according to a second embodiment of the present invention.

FIG. 19A shows a diagram of CVs recorded in 0.1M KCl at 100 mV/s showing the extremely high enhancement in the capacitive currents according to the second embodiment of the present invention.

FIG. 19B shows a diagram of CVs recorded in 0.1M KCl at 50 mV/s showing the extremely high enhancement in the capacitive currents according to the second embodiment of the present invention.

FIG. 19C shows diagrams of CVs for the device in 0.1M KCl before (on the left) and after MnO₂ deposition (on the right) according to the second embodiment of the present invention.

FIG. 20 shows a diagram of CVs recorded during 10 cycles (20 sweep segments) of MnO₂ deposition at 100 mV/s in 10 mM KMnO₄ and potential scan limits of −1V to +1V according to a third embodiment of the present invention.

FIG. 21A shows a diagram of CVs recorded in 0.1M KCl at 100 mV/s showing the extremely high enhancement in the capacitive currents according to the third embodiment of the present invention.

FIG. 21B shows a diagram of CVs recorded in 0.1M KCl at 50 mV/s showing the extremely high enhancement in the capacitive currents according to the third embodiment of the present invention.

FIG. 22 shows a diagram of CVs recorded during 40 cycles (80 sweep segments) of MnO₂ deposition at 100 mV/s in 10 mM KMnO₄ and potential scan limits of −1V to +1V according to a fourth embodiment of the present invention.

FIG. 23A shows a diagram of the assembly used for electrochemical deposition and characterization of MnO₂/CNT/Graphite structure according to the fourth embodiment of the present invention.

FIG. 23B shows an ultracapacitor cell (device) after 40 cycles of MnO₂ deposition and removing it from the Teflon rod, according to the fourth embodiment of the present invention.

FIG. 24A shows a diagram of CVs recorded in 0.1M KCl at 100 mV/s showing the extremely high enhancement in the capacitive currents according to the fourth embodiment of the present invention.

FIG. 24B shows a diagram of CVs recorded in 0.1M KCl at 50 mV/s showing the extremely high enhancement in the capacitive currents according to the fourth embodiment of the present invention.

FIG. 24C shows diagrams of CVs for the device in 0.1M KCl before (on the left) and after MnO₂ deposition (on the right) according to the fourth embodiment of the present invention.

### DETAILED DESCRIPTION OF THE INVENTION

The present invention is more particularly described in the following examples that are intended as illustrative only since numerous modifications and variations therein will be apparent to those skilled in the art. Various embodiments of the invention are now described in detail. Referring to the drawings, like numbers indicate like components throughout the views. As used in the description herein and throughout the claims that follow, the meaning of “a”, “an”, and “the” includes plural reference unless the context clearly dictates otherwise. Also, as used in the description herein and throughout the claims that follow, the meaning of “in” includes “in” and “on” unless the context clearly dictates otherwise. Moreover, titles or subtitles may be used in the specification for the convenience of a reader, which shall have no influence on the scope of the present invention. Additionally, some terms used in this specification are more specifically defined below.

### DEFINITIONS

The terms used in this specification generally have their ordinary meanings in the art, within the context of the invention, and in the specific context where each term is used. Certain terms that are used to describe the invention are discussed below, or elsewhere in the specification, to provide additional guidance to the practitioner regarding the description of the invention. For convenience, certain terms may be highlighted, for example using italics and/or quotation marks. The use of highlighting has no influence on the scope and meaning of a term; the scope and meaning of a term is the same, in the same context, whether or not it is highlighted. It will be appreciated that same thing can be said in more than one way. Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification including examples of any terms discussed herein is illustrative only, and in no way limits the scope and meaning of the invention or of any exemplified term. Likewise, the invention is not limited to various embodiments given in this specification.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, if any, the term “scanning electron microscope” or its abbreviation “SEM” refers to a type of electron microscope that images the sample surface by scanning it with a high-energy beam of electrons in a raster scan pattern. The electrons interact with the atoms that make up the sample producing signals that contain information about the sample's surface topography, composition and other properties such as electrical conductivity.

As used herein, if any, the term “transmission electron microscopy” or its abbreviation “TEM” refers to a microscopy technique whereby a beam of electrons is transmitted through an ultra thin specimen, interacting with the specimen as it passes through. An image is formed from the interaction of the electrons transmitted through the specimen; the image is magnified and focused onto an imaging device, such as a fluorescent screen, on a layer of photographic film, or to be detected by a sensor such as a CCD camera.

As used herein, if any, the term “X-ray photoelectron spectroscopy” or its abbreviation “XPS” refers to a method used to determine the composition of the top few nanometers of a surface. It involves bombarding the surface with x-rays above a threshold frequency which leads to generation of photoelectrons from the core-level of the atoms, leaving behind holes. Based on conservation of energy, the kinetic energy can be given by ½ mₑv²=hυ−E_{B}−φ, where mₑ is the mass of the electron, v is the electron velocity after ejection, h is the Plank's constant, υ is the frequency of incident x-ray, E_{B} is the electron binding energy and φ is the work function of the material being studied. The binding energy can be plotted versus photoelectrons' intensity, and the peaks observed are characteristic of the elements.

As used herein, “nanoscopic-scale”, “nanoscopic”, “nanometer-scale”, “nanoscale”, “nanocomposites”, “nanoparticles”, the “nano-” prefix, and the like generally refers to elements or articles having widths or diameters of less than about 1 μm, preferably less than about 100 nm in some cases. In all embodiments, specified widths can be smallest width (i.e. a width as specified where, at that location, the article can have a larger width in a different dimension), or largest width (i.e. where, at that location, the article's width is no wider than as specified, but can have a length that is greater).

As used herein, a “nanostructure” refers to an object of intermediate size between molecular and microscopic (micrometer-sized) structures. In describing nanostructures, the sizes of the nanostructures refer to the number of dimensions on the nanoscale. For example, nanotextured surfaces have one dimension on the nanoscale, i.e., only the thickness of the surface of an object is between 0.1 and 1000 nm. Nanotubes have two dimensions on the nanoscale, i.e., the diameter of the tube is between 0.1 and 1000 nm; its length could be much greater. Finally, sphere-like nanoparticles have three dimensions on the nanoscale, i.e., the particle is between 0.1 and 1000 nm in each spatial dimension. A list of nanostructures includes, but not limited to, nanoparticle, nanocomposite, quantum dot, nanofilm, nanoshell, nanofiber, nanoring, nanorod, nanotube, and so on.

As used herein, “plurality” means two or more.

As used herein, the terms “comprising”, “including”, “carrying”, “having”, “containing”, “involving”, and the like are to be understood to be open-ended, i.e., to mean including but not limited to.

### OVERVIEW OF THE INVENTION

This invention discloses, among other things, a novel hybrid electrochemical ultracapacitor that combines desirable attributes such as extremely high energy-power density, excellent life-cycle reliability and safety characteristics, with low production cost and has the potential for widespread deployment in energy delivery/storage applications, and innovative methods/approaches of making the same. In the innovative approach, carbon nanotubes (CNTs) or carbon fibers/nanofibers (CFs) are grown directly on conducting flexible (or rigid) substrates to reduce contact resistances. The CNTs or CFs have excellent electrical conductivity and provide extremely large effective surface area essential for generating higher capacitance values. The more controllable CNT or CF nanoarchitectures for optimum attachments of inexpensive pseudocapacitive manganese-dioxide (MnO₂) nanoparticles to enhance charge efficiency and energy-power capacity are also exploited. The approaches in one embodiment employ a “green” electrolyte that increases cell voltages.

In one aspect of the invention, the ultracapacitor utilizes an advanced nanoarchitectured pseudocapacitive electrode to enhance energy density with a three dimension (3D) nanostructured high-surface-area CNT or CF conductor electrode for optimum pseudocapacitive MnO₂ nanoparticle impregnation, and an ionic electrolyte to operate with greater cell voltage. When charging, the positive cations in the electrolyte are attracted to the negative electrode, and the negative anions to the positive electrode. Both negative and positive ions in the electrolyte accumulate at the electrode surface to compensate for the electronic charge. Hence, electrical energy is stored inside the electrochemical double layer (the Helmholtz layer) at the electrode-electrolyte interface. This effect is further enhanced by the fast reversible redox faradaic pseudocapacitance induced by the MnO₂ nanoparticles. The thickness of the double layer (varies between 5 and 10 angstroms) is usually determined by the electrolyte concentration and the ion size. Since the capacitance is proportional to the electrode area, C=εA/d, higher capacitance can be obtained by making electrodes from nanostructured CNTs of CFs for attachment of the nanoscaled MnO₂ to optimize the pseudocapacitive effect with very large effective surface areas.

According to the invention, the ultracapacitor stores electrical charges at an electrode-electrolyte interface, with CNTs as a current conductor and MnO₂ pseudocapacitor nanoparticles as electrodes. The nanoarchitectured network structure formed by nanotubes allows the attachment of nano-sized MnO₂ particles to them, so that each individual nanotube may be covered with a very thin layer of MnO₂. Therefore, each nanotube serves as a miniature current collector while the attached MnO₂ thin coating serves as tiny electrodes. Because of the excellent electronic conductivity of CNTs, the total equivalent series resistance (ESR) is significantly reduced and the power density is enhanced via P=V²/4R. The fine tailoring of the nano-scale attachment of the electrode material has resulted in optimal performance in terms of energy, power, and cycling capabilities. Moreover, this system can utilize potassium chloride aqueous solution as the electrolyte, which is more environmentally friendly than other alternatives. Accordingly, a specific capacitance of the CNT/MnO₂ electrode 100-1000× higher than as-grown CNT-only thin-film electrodes and >50× larger energy density than conventional electrochemical capacitors are achieved. With further optimization of electrode configurations and the cell voltage, the specific capacitance is increased and energy-power are maximized, thereby achieving a transformational energy storage/delivery system both fundamentally and technologically.

In one aspect, the present invention relates to an ultracapacitor utilizing a novel approach, in which as-grown nanostructured CNTs (first nanostructures) provide an excellent conductor network for the plate with high surface area for the attachment of nano-particles of an active material, such as pseudocapacitive nano-particles of MnO₂ (second nanostructures). The resulting enhanced surface area maximizes the charge efficiency and the power density, and at the same time the series resistance is reduced. In the following description, the MnO₂ pseudocapacitive nano-particles are used as an exemplary active material to describe the invention for the benefits of readers but not as a limitation. However, it is understood that other active materials, including Ag₂O, FeS, RuO₂, NiOₓ, CoOₓ, V₂O₅ or a mixture thereof, can be utilized to practice the invention.

In some embodiments, the structure of the ultracapacitor can be modified for the purpose of various applications. For example, in one embodiment, the substrate may include a flexible conducting plate such that the ultracapacitor can be formed in different shapes, such as a rolled shape or a cylindrical shape. In one embodiment, a plurality of plates is alternately aligned and electrically connected to two different potentials to form a stacked ultracapacitor. In one embodiment, the ultracapacitor is used in an electrical energy storage device, and the materials and dimensions of the plates are specifically designed such that the specific capacitance is greater than 500 F/g.

According to the invention, the fabrication of the ultracapacitor begins with growth of current collectors, e.g., CNTs or CFs directly on substrates. The substrates can be rigid substrates such as highly doped silicon substrates, or flexible substrates, such as metallic foils (e.g. molybdenum), and very inexpensive graphite foil. The CNTs or CFs growth can be achieved using catalyst assisted MPECVD (microwave plasma enhanced chemical vapor deposition) or HFCVD (hot filament chemical vapor deposition) or thermal chemical vapor deposition processes. As such, the contact resistance can also be minimized.

In one embodiment, the CNTs and CFs are present as a continuous film on the entire substrate or over the region of interest, which is corresponding to a configuration of planar CNTs, CFs. In another embodiment, pre-determined array patterns of CNTs or CFs are created on the silicon substrates, for example, by using typical silicon microfabrication technology, which is corresponding to a configuration of micropatterned CNT, CF arrays. The individual array element can be circular, square or rectangular, other geometrical shapes and is separated from the nearest neighbor by a finite distance, with a thin layer of silicon dioxide providing electrical isolation. After catalyst deposition, CNTs and CFs are grown in selective regions based on the array design.

Further, two processes are utilized for the pseudocapacitive material attachment or incorporation onto the CNTs and CFs. One is a dripping process, which is implemented by using a suspension of MnO₂. The suspension is made in different liquid media, for example, acetone or water. The other process is in-situ electrodeposition of MnO₂ on the current collectors, where an aqueous solution of KMnO₄, is used and MnO₄⁻ is directly reduced to MnO₂ on the CNTs and CFs surface.

These and other aspects of the present invention are more specifically described below.

### IMPLEMENTATIONS AND EXAMPLES OF THE INVENTION

Without intent to limit the scope of the invention, exemplary methods and their related results according to the embodiments of the present invention are given below. Note that titles or subtitles may be used in the examples for convenience of a reader, which in no way should limit the scope of the invention. Moreover, certain theories are proposed and disclosed herein; however, in no way they, whether they are right or wrong, should limit the scope of the invention so long as the invention is practiced according to the invention without regard for any particular theory or scheme of action.

### Example One

### Planar Ultracapacitor

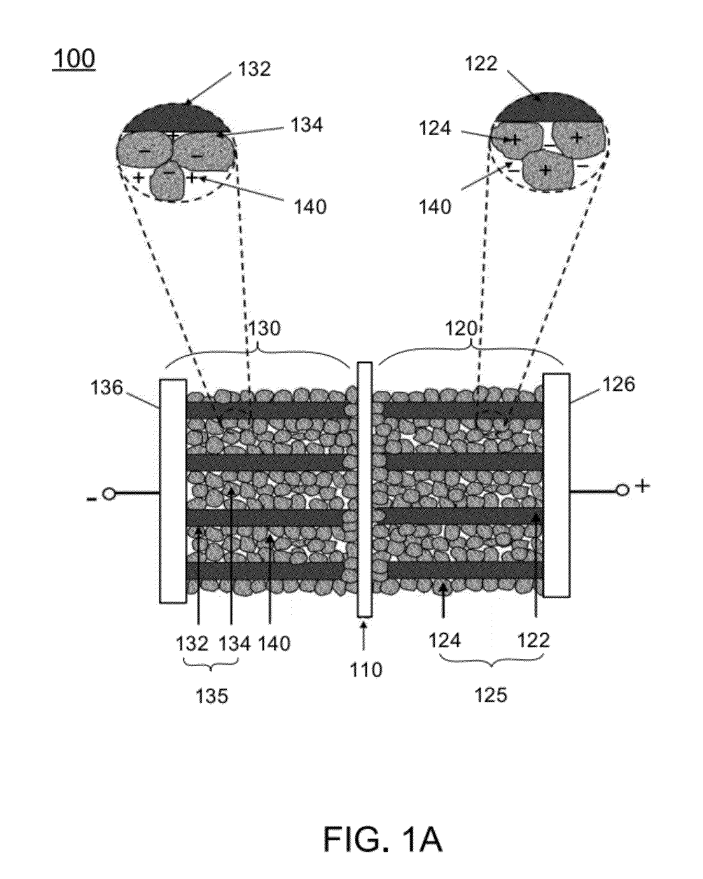

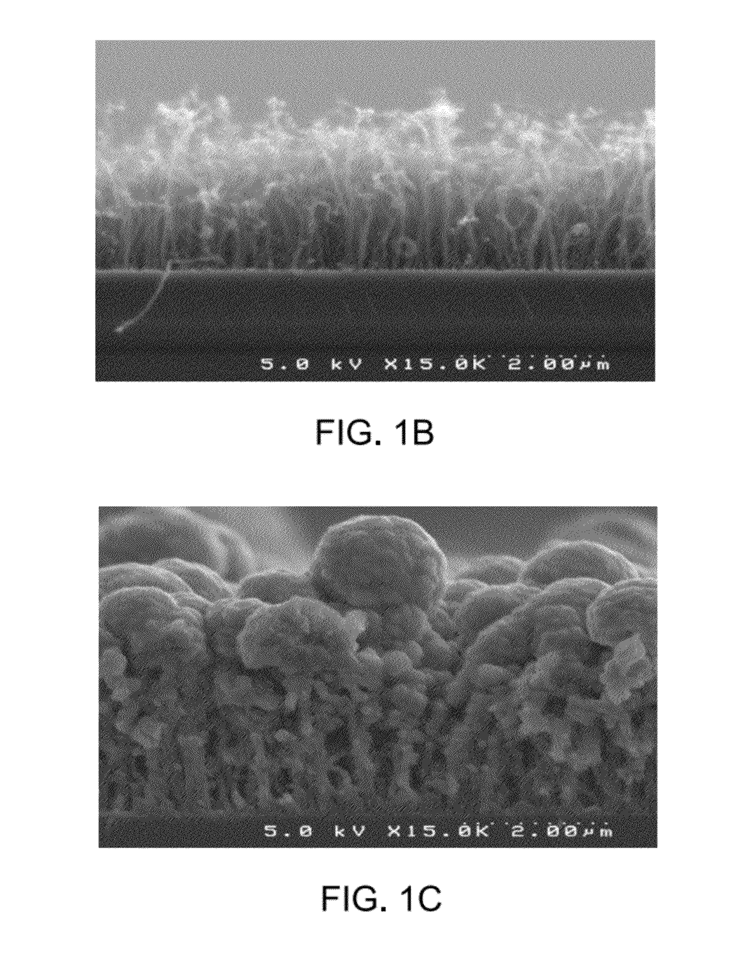

FIG. 1A shows schematically an enlarged diagram of a symmetric ultracapacitor 100 according to one embodiment of the present invention. It should be noted that, although a symmetric structure is shown in FIG. 1A, the concept of the embodiment or the present invention also applies to an asymmetric structure where the two electrodes are of different types of materials, dimensions or shapes. Further, the structure of the ultracapacitor shown in FIG. 1A is in an out-of-scale and enlarged diagram for better illustration of the formation, particularly the nanostructures, of the ultracapacitor 100.

As shown in FIG. 1A, the ultracapacitor 100 includes a separator 110, a first plate 120 (for example, the plate on the right side of FIG. 1A), and a second plate 130 (for example, the plate on the left side of FIG. 1A). The first plate 120 is adapted to be coupled to a first potential (for example, the positive potential shown by the symbol “+”), and the second plate 130 is adapted to be coupled to a second potential (for example, the negative potential shown by the symbol “−”).

The separator 110 is positioned between the first plate 120 and the second plate 130 to form the partition between the first and second plates 120 and 130. In one embodiment, the separator 110 can be porous. The separator 110 may be a piece of thin filter paper or an anodized Al₂O₃ perforated film or other polymeric separator films, which have respectively been proven to perform well as porous separators.

Each of the first and second plates 120 and 130 includes a substrate 126/136, first nanostructures 122/132 formed on the substrate 126/136 and second nanostructures 124/134 different from the first nanostructures 122/132. The second nanostructures 124/134 are attached to the first nanostructures 122/132. Further, an electrolyte solution 140 fills in the space between the substrate 126/136, the first nanostructures 122/132, and the second nanostructures 124/134 such that the electrolyte solution 140 is in contact with the first nanostructures 122/132, the second nanostructures 124/134 and the substrate 126/136 in each plate 120/130.

The two substrates 126 and 136 are positioned outside to bind the respective first and second plates 120 and 130. In one embodiment, each substrate 126/136 can be a rigid conducting substrates including highly doped silicon. In another embodiment, the substrates 126/136 can be a flexible conducting film such as metallic foils (e.g., Molybdenum), graphite or corrosion resistant metal foils.

The first nanostructures 122 and 132 of the first and second plates 120 and 130 are adapted as current collectors, and can be carbon-based nanoscale materials, such as carbon nanotubes (CNTs) or carbon fibers/nanofibers (CFs), which have excellent electrical conductivity and provide extremely large effective surface area essential for generating higher capacitance values. These CNTs or CFs can be grown directly on the substrates, as shown in FIG. 1B, using a catalyst assisted MPECVD or HFCVD or thermal CVD processes. In this case, the contact resistance can also be minimized. In one embodiment, diameters of the CNTs or CFs are in the range of about 1.0-1,000.0 nm.

The second nanostructures 124 and 134 of the first and second plates 120 and 130 are nano-particles of an active material, i.e., pseudocapacitive material. In one embodiment, the active material includes MnO₂. Thus, the first nanostructures 122 and 132 and the second nanostructures 124 and 134 form the CNT/MnO₂ electrode structures 125 and 135 for the first and second plates 120 and 130, respectively. In certain embodiments, the active material can be silver oxide, iron sulfide, RuO₂, NiOₓ, CoOₓ, V₂O₅ or mixtures thereof, or any other pseudocapacitive materials. In one embodiment, sizes/diameters of the nano-particles of the active material are in the range of 1.0-1000.0 nm.

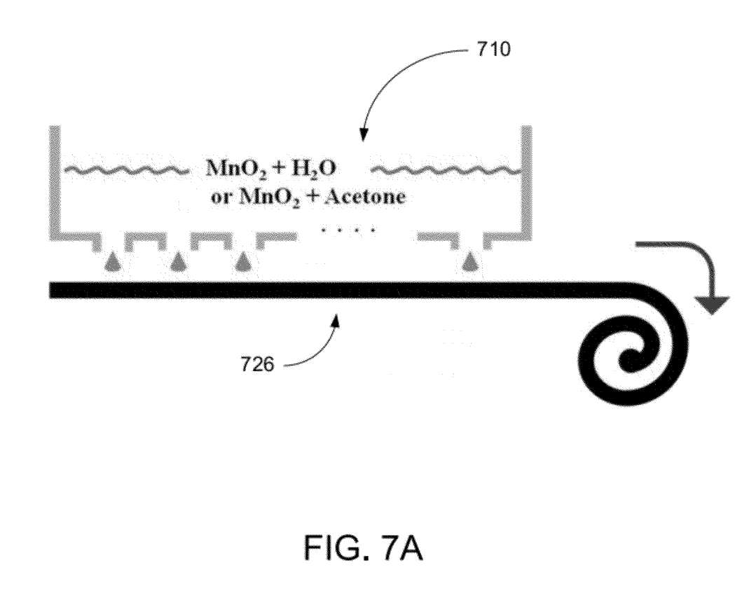

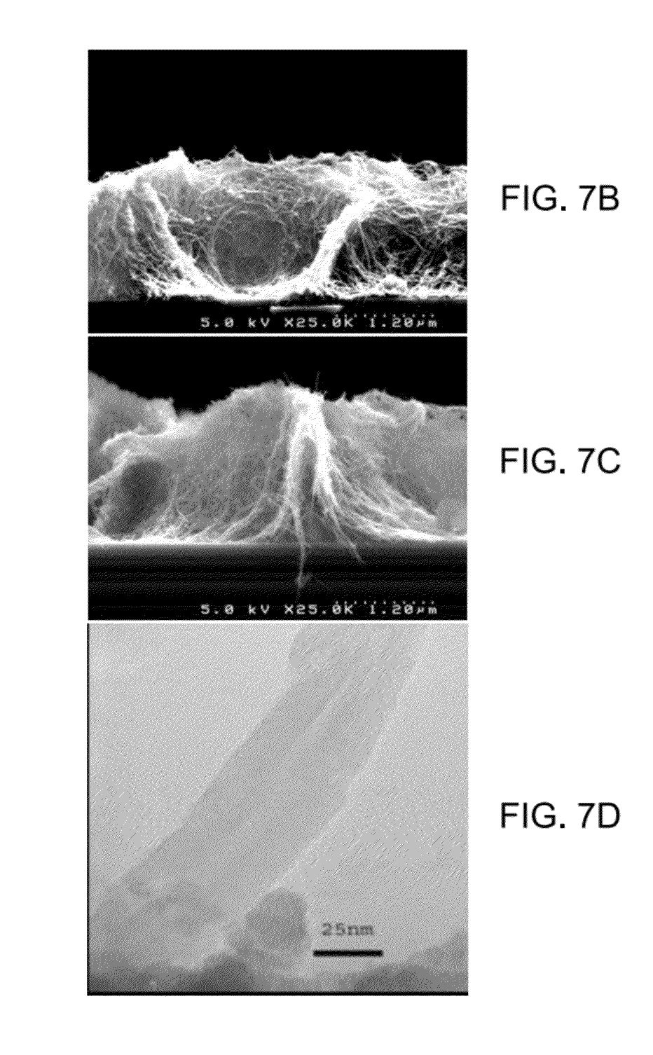

In one embodiment, the second nanostructures (active material) 124 and 134, e.g., MnO₂, are incorporated or impregnated into the first nanostructures 122 and 132, e.g., vertically grown CNTs or CFs, as shown in FIGS. 7B and 7C, by preparing a suspension of the active material in different liquid media, such as acetone and water, and dripping the suspension into the first nanostructures 122 and 132 grown on the substrates 120 and 130, respectively, so as to attach the active material of MnO₂ onto the first nanostructures 122 and 132, i.e., the current collectors. In another embodiment, the active material of MnO₂ is incorporated or impregnated by in-situ electrodeposition of MnO₂ directly on the current collectors. In this process, an aqueous solution of potassium permanganate (KMnO₄) is used and MnO₄⁻ is directly reduced to MnO₂ on the CNTs and CFs surface.

For the first plate 120, a partially enlarged view is provided at the top right of FIG. 1A for better illustration of the first plate 120. As disclosed above, the first plate 120 is adapted to be coupled to the first potential (the positive potential). Thus, the first nanostructures 122, such as the CNTs or CFs, transmit the positive potential to the second nanostructures 124, such as the nano-particles of MnO₂. Accordingly, the nano-particles 124 contain positive cations, and the electrolyte solution 140 in the neighboring area of the nano-particles 124 contains negative anions.

Similarly, for the second plate 130, a partially enlarged view is provided at the top left of FIG. 1 for better illustration of the first plate 130. As disclosed above, the second plate 130 is adapted to be coupled to the second potential (the negative potential). Thus, the first nanostructures 132 transmit the negative potential to the second nanostructures 134. Accordingly, the nano-particles of the second nanostructures 134 contain negative anions, and the electrolyte solution 140 in the neighboring area of the nano-particles of the second nanostructures 134 contains positive cations.

The ultracapacitor structure 100 shown in FIG. 1A stores electrical charge at an electrode-electrolyte interface, with vertically aligned CNTs as current conductors and MnO₂ pseudocapacitor nanoparticles as electrodes. The nanoarchitectured network structure formed by nanotubes allows the attachment of nano-sized MnO₂ particles to them, so that each individual nanotube is covered with a very thin layer of nano-sized MnO₂. Therefore, each nanotube serves as a miniature current collector while the attached MnO₂ thin coating serves as tiny electrodes. Because of the excellent electronic conductivity of CNT, the total equivalent series resistance (ESR) is significantly reduced and the power density is enhanced via P=V²/4R.

In one embodiment, fabrication of the ultracapacitor begins with the growth of CNTs or CFs on a rigid or flexible conducting substrate (for example, graphite or corrosion resistant metal foil). In this configuration, the CNTs and CFs are present as a continuous film on the entire substrate or over the region of interest on the substrate. The grown CNTs or CFs may have diameters or thicknesses of about 1.0-1,000.0 nm. The CNT or CF growth is followed by the deposition of MnO₂ nanoparticles, using a dripping/wetting process or other methods including electrodeposition. Electrical leads are connected to the corresponding conducting substrates. Thin filter paper and anodized Al₂O₃ perforated film or other polymeric separator films have each performed well as porous separators. The assembled package is then housed in a container and immersed in an electrolyte medium. The resulting structure constitutes a basic form of electrochemical ultracapacitor from which various cell configurations can be derived. The growth of CNTs directly on a conducting substrate and the intimate contact between the MnO₂ nanoparticles and CNTs provides a large capacitance per unit volume, low internal resistance, and negligible leakage current. When the conducting substrate happens to be flexible graphite foil, the growth of CNTs achieves similar atomic bonding with high mechanical strength.

FIG. 1B shows a scanning electron microscope (SEM) image of CNTs grown on the substrate, while FIG. 1C shows an SEM image of MnO₂ coated CNTs grown on the substrate according to one embodiment of the present invention

### Example Two

### Cylindrical Ultracapacitor

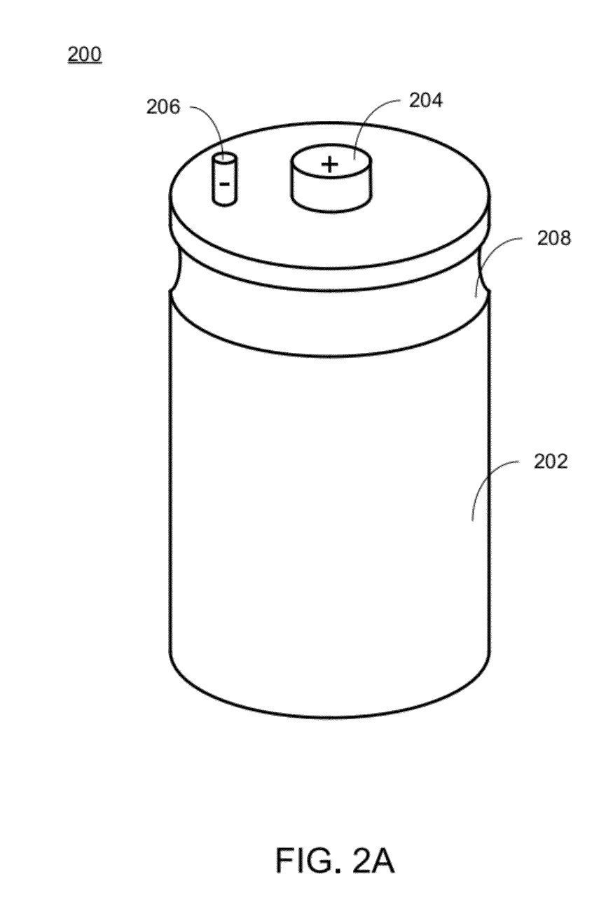

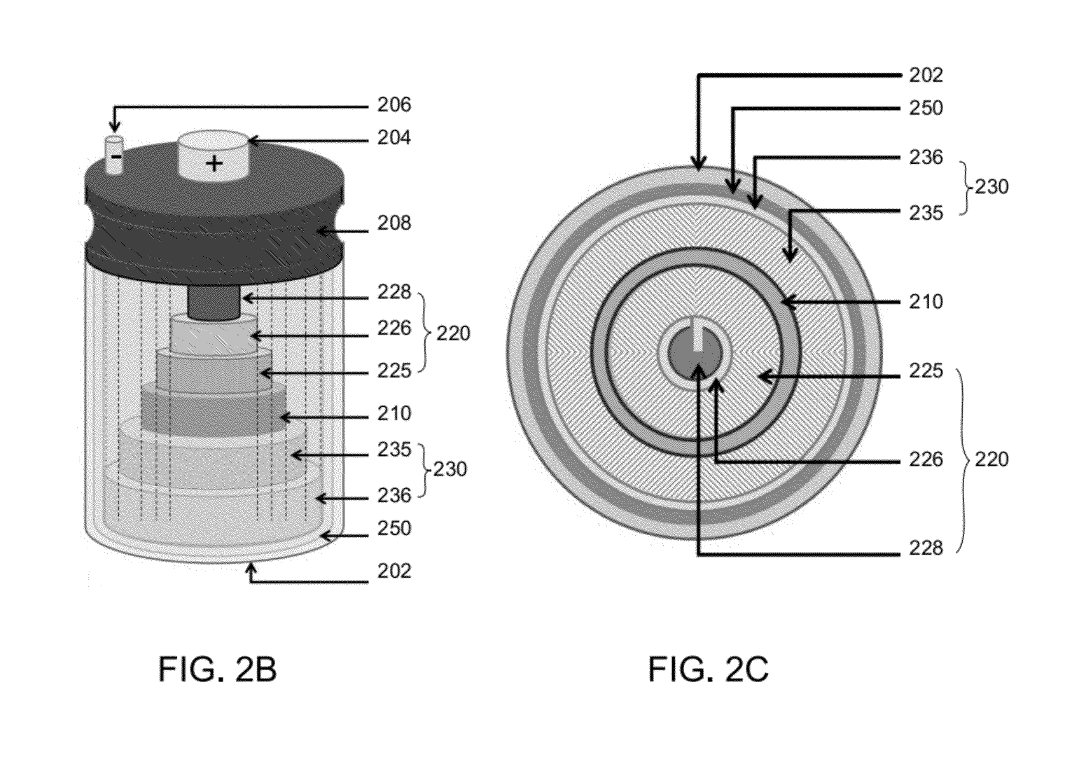

Referring to FIGS. 2A-2C, a symmetric ultracapacitor 200 is schematically shown according to one embodiment of the present invention. It should be noted that, although a symmetric structure is shown in FIGS. 2A-2C, the concept of the embodiment or the present invention also applies to an asymmetric structure where the two electrodes are of the same or different type of material, dimension or shape. Further, the structures of the ultracapacitor shown in FIGS. 2A-2C are in an out-of-scale and enlarged diagram for better illustration of the formation of the ultracapacitor 200.

FIG. 2A shows schematically a perspective view of the symmetric ultracapacitor 200 with a cylindrical shape, FIG. 2B shows schematically a perspective view of the internal structure of the symmetric ultracapacitor 200 of FIG. 2A, and FIG. 2C shows schematically a cross section view of the internal structure of the symmetric ultracapacitor 200 of FIG. 2B. In this embodiment, the symmetric ultracapacitor 200 is an electrical energy storage device, such as an electrochemical ultracapacitor cell, which has a cylindrical outer casing 202, a positive electrical terminal 204 (shown by the symbol “+”), a negative electrical terminal 206 (shown by the symbol “−”), and a rubber cap seal 208 provided to seal the electrical terminals 204 and 206 to the outer casing 202. Further, the internal structure of the symmetric ultracapacitor 200 includes a separator 210, a first plate 220, a second plate 230, and an insulating layer 250.

The first plate 220 includes a substrate 226, a first CNT/MnO₂ electrode structure 225, and a conducting rod 228. The second plate 230 includes a substrate 236 and a second CNT/MnO₂ electrode structure 235. The first and second CNT/MnO₂ electrode structures 225 and 235 are similar to the CNT/MnO₂ electrode structures 125 and 135 of the ultracapacitor 100 shown in FIG. 1A, including the first nanostructures with a coating of second nanostructures. Please refer to the above description for the details of the first and second nanostructures of the first and second CNT/MnO₂ electrode structures 225 and 235.

As shown in FIGS. 2B and 2C, the conducting rod 228, the first substrate 226, the first CNT/MnO₂ electrode structure 225, the separator 210, the second CNT/MnO₂ electrode structure 235, the second substrate 236, the insulating layer 250 and the outer casing 202 are formed as concentric cylindrical layers. In other words, the electrical energy storage device 200 is a double-layer concentric ultracapacitor, and the separator 210 is positioned between the first plate 220 (which is inside the separator 210) and the second plate 230 (outside the separator 210). The conducting rod 228, which can be made with graphite or any other conducting materials, is coupled to the positive electrical terminal 204 such that the first plate 220 is coupled to the first potential (the positive potential), and the second substrate 236 is coupled to the negative electrical terminal 206 such that the second plate 230 is coupled to the second potential (the negative potential). The insulating layer 250 is provided to pack the internal ultracapacitor structures such that insulation between the outer casing 202 and the internal ultracapacitor structures can be ensured.

In one embodiment, an electrolyte solution (not shown) can be injected and filled in the space of the first and second CNT/MnO₂ electrode structures 225 and 235 such that the first and second CNT/MnO₂ electrode structures 225 and 235 can be soaked and immersed in the electrolyte solution, and the electrolyte solution can be in contact with the arrays of the first nanostructures with the coatings of the second nanostructures.

It should be noted that the materials and the dimensions of the first plate 220 and the second plate 230 determine the electrical performance of the electrical energy storage device. For example, the specific energy density of the electrical energy storage device Wh/kg is determined by the following formula:

Wh/kg=(1/8)(F/g)(V²/3.6)

where F/g is the specific capacitance of the electrode material, and V is the cell voltage, which is dependent primarily on the electrolyte solution used in the electrical energy storage device. In one embodiment, the first plate 220 and the second plate 230 are formed with materials and with dimensions such that the specific capacitance is greater than 500 F/g.

### Example Three

### Multi-Stack Ultracapacitor Cell with Rolled Structures

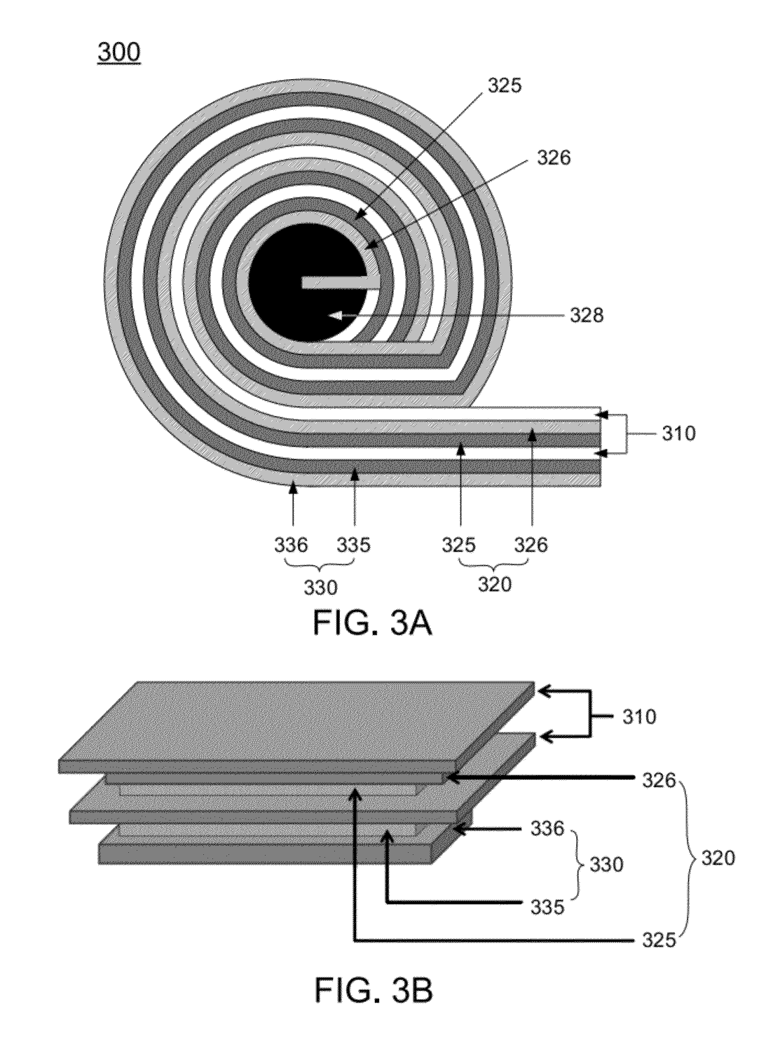

Referring to FIGS. 3A and 3B, an ultracapacitor cell 300 with a multi-stack structure is schematically shown according to one embodiment of the present invention. The structures of the ultracapacitor cell shown in FIGS. 3A and 3B are in an out-of-scale and enlarged diagram to better illustrate the formation of the ultracapacitor 300. The symmetric ultracapacitor cell 300 is an electrical energy storage device, such as an electrochemical ultracapacitor cell, which has a multi-stacked configuration. The symmetric ultracapacitor cell 300 includes a plurality of separators 310, a first plate 320, and a second plate 330.

The first plate 320 includes a first substrate 326 and a first CNT/MnO₂ electrode structure 325. The second plate 330 includes a second substrate 336 and a second CNT/MnO₂ electrode structure 335. The first and second CNT/MnO₂ electrode structures 325 and 335 are similar to the CNT/MnO₂ electrode structures 125 and 135 of the ultracapacitor 100 shown in FIG. 1A, including the array of first nanostructures with a coating/attachment of the second nanostructures. Please refer to the above description for the details of the first and second nanostructures of the first and second CNT/MnO₂ electrode structures 325 and 335.

It should be noted that FIG. 3B shows two separators. However, there can be more stacked layers. One of the separators 310 is positioned between the first plate 320 and the second plate 330 to form the partition between the plates, and the other separator 310 is positioned on the first plate 320 such that the symmetric ultracapacitor cell 300 can be deformed, e.g., twisted and rolled to form a rolled multi-stack structure, as shown in FIG. 3A.

As shown in FIG. 3A, the multi-stack structure of the symmetric ultracapacitor in FIG. 3B is rolled to form a “sandwich” stack layer, and the first substrate 326 is coupled to a conducting rod 328, which is similar to the conducting rod 228 in FIGS. 2B and 2C. The two layers of separators 310 are necessarily inserted in the “sandwich” such that the first plate 320 and the second plate 330 can be separated.

In one embodiment, the first and second substrates 326 and 336 are flexible conducting plates such that they can be deformed and rolled as shown in FIG. 3A. In one embodiment, the separators 310 are porous, and may be a piece of thin filter paper or an anodized Al₂O₃ perforated film or other polymeric separator films, which have been proven to perform well as porous separators.

In one embodiment, an electrolyte solution (not shown) is filled in the space of the first and second CNT/MnO₂ electrode structures 325 and 335 such that the electrolyte solution can be in contact with the arrays of the first nanostructures with the coatings of the second nanostructures.

It should be appreciated that the multi-stack structure of the symmetric ultracapacitor in FIGS. 3A and 3B may have more than one layer of the first plate 320 and the second plate 330, and additional separators 310 may be required to ensure all of the first plates 320 are separated with the neighboring second plates 330.

### Example Four

### Multi-Layer Ultracapacitor Cell with Conducting Track Members

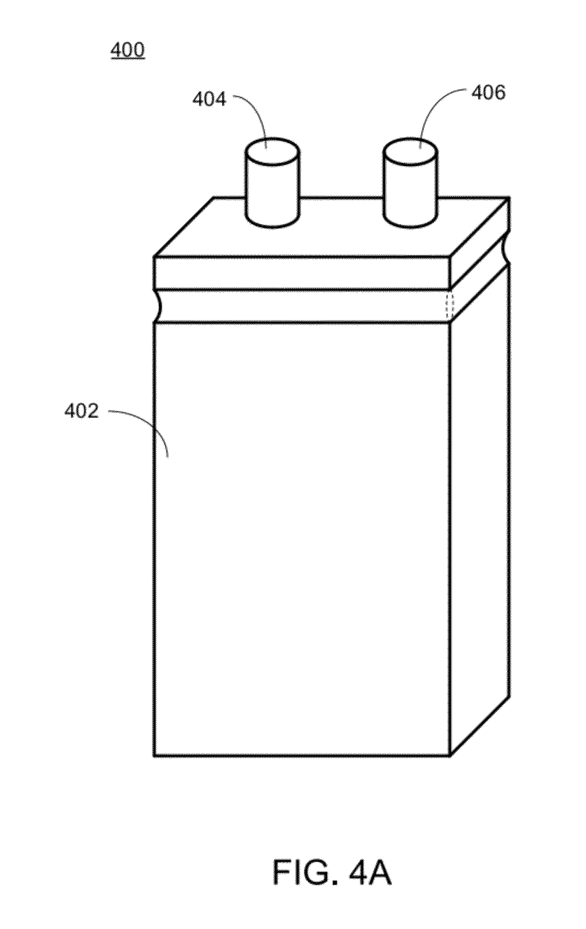

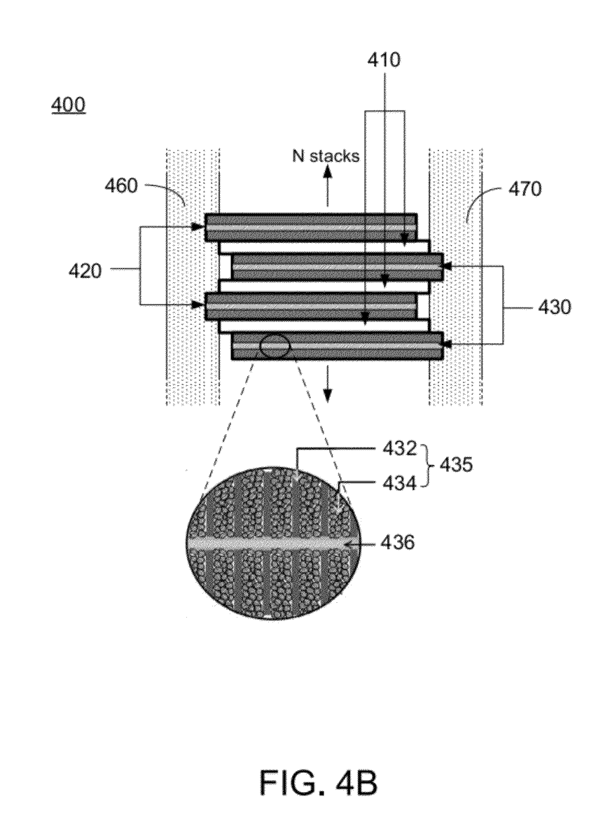

FIGS. 4A and 4B show schematically an ultracapacitor cell 400 according to one embodiment of the present invention, where the structures of the ultracapacitor cell 400 are shown in an out-of-scale and enlarged diagram to better illustrate the formation of the ultracapacitor 400.

FIG. 4A shows schematically a perspective view of an ultracapacitor cell 400 with a rectangular shape, while FIG. 4B shows schematically a top view of the internal structure of the ultracapacitor cell 400. In this exemplary embodiment, the ultracapacitor cell 400 is an electrical energy storage device, such as an electrochemical ultracapacitor cell, which has a rectangular outer casing 402, and two electrical terminals 404 and 406 coupled to two different potentials. Further, the internal structure of the symmetric ultracapacitor cell 400 includes a first conducting track member 460, a second conducting track member 470, a plurality of separators 410, a plurality of first plates 420, and a plurality of second plates 430.

As shown in FIG. 4B, the first conducting track member 460 and the second conducting track member 470 are positioned apart to define a space therebetween. The plurality of first plates 420 is respectively electrically coupled to the first conducting track member 460 only, and the plurality of second plates 430 is respectively electrically coupled to the second conducting track member 470 only. Thus, the first conducting track member 460 and the second conducting track member 470 can be respectively coupled to the two electrical terminals 404 and 406 to provide different potentials to the first and second plates 420 and 430.

Each of the first and second plates 420 and 430 comprises a conducting substrate, and an array of first nanostructures with a coating of second nanostructures different from the first nanostructures formed on the conducting substrate. For example, an enlarged view of one of the second plates 430 is shown in FIG. 4B, which includes the conducting substrate 436, the array of the first nanostructures 432 and the coating of the second nanostructures 434. In one embodiment, the first and second nanostructures 432 and 434 form the CNT/MnO₂ electrode structure 435, which is similar to the CNT/MnO₂ electrode structures as described above, and detailed descriptions are hereinafter omitted.

Further, the separators 410 are positioned such that at least one separator 410 is positioned between any first plate 420 and its adjacent second plate 430. In other words, there is at least one separator 410 between any pair of adjacent first plate 420 and second plate 430.

In one embodiment, an electrolyte solution (not shown) is injected and filled in the space of the CNT/MnO₂ electrode structures such that the CNT/MnO₂ electrode structures can be soaked and immersed in the electrolyte solution, and the electrolyte solution can be in contact with the arrays of the first nanostructures with the coatings of the second nanostructures.

### Example Five

### Ultracapacitor Cell with Disk Structures

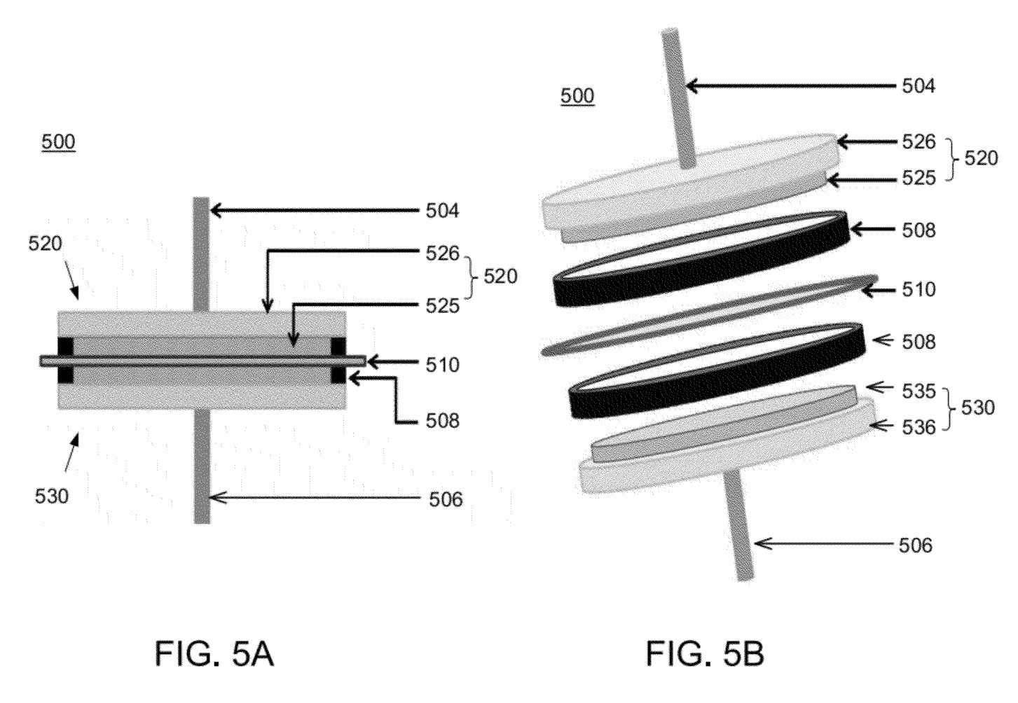

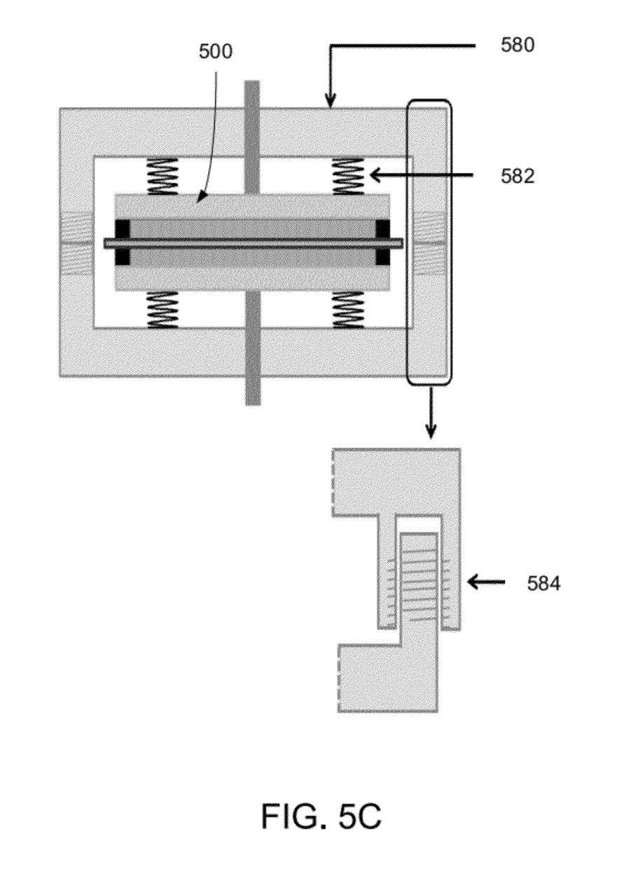

FIGS. 5A and 5B show respectively cross-sectional and explosive views of an ultracapacitor cell 500 with a disk-like structure according to one embodiment of the present invention. In this exemplary embodiment, the ultracapacitor cell 500 is an electrical energy storage device, such as an electrochemical ultracapacitor cell, which has a symmetrical disk shape, and the ultracapacitor 500 includes two electrical terminals 504 and 506 coupled to two different potentials. Further, the ultracapacitor cell 500 includes a separator 510, a first plate 520, a second plate 530, and two seal rings 508.

As shown in FIGS. 5A and 5B, the first plate 520 includes a substrate 526 and a first CNT/MnO₂ electrode structure 525. The second plate 530 includes a substrate 536 and a second CNT/MnO₂ electrode structure 535. Specifically, the first and second CNT/MnO₂ electrode structures 525 and 535 are similar to the CNT/MnO₂ electrode structures 125 and 135 in FIG. 1A, including the array of first nanostructures with a coating of second nanostructures. Details of the first and second nanostructures of the first and second CNT/MnO₂ electrode structures 525 and 535 are hereinafter omitted.

In one embodiment, an electrolyte solution (not shown) can be injected and filled in the space of the first and second CNT/MnO₂ electrode structures 525 and 535 such that the first and second CNT/MnO₂ electrode structures 525 and 535 can be soaked and immersed in the electrolyte solution, and the electrolyte solution can be in contact with the arrays of the first nanostructures with the coatings of the second nanostructures.

When the ultracapacitor 500 is assembled, the first and second substrates 526 and 536 are respectively coupled to the two electrical terminals 504 and 506 such that the two different potentials can be provided to the first and second plates 520 and 530. The separator 510 is positioned between the first and second plates 520 and 530, and the seal rings 508 are positioned to enclose the first and second CNT/MnO₂ electrode structure 525 and 535 to form a package of the ultracapacitor 500, thus ensuring isolation and preventing from leakage of the electrolyte solution.

Further, FIG. 5C shows schematically a cross-sectional view of an application of the ultracapacitor of FIG. 5A. In FIG. 5C, the ultracapacitor 500 is positioned in a casing 580 with a plurality of springs 582 provided to ensure that an edge-margin exists between the ultracapacitor 500 and the casing 580. In one embodiment, the casing 580 can be made of isolating materials, such as PVC, which can be sealed by heat or other methods. FIG. 5C shows a heat activated permanent seal 584, which ensures the isolation of the casing 580.

### Example Six

### Fabrication of CNT/MnO₂ Ultracapacitors

According to the invention, the fabrication of an ultracapacitor begins with growth of current collectors, e.g., CNTs or CFs directly on substrates. The CNTs or CFs have excellent electrical conductivity and provide extremely large effective surface area essential for generating higher capacitance values. The substrates can be rigid substrates such as highly doped silicon substrates, or flexible substrates, such as metallic foils (e.g. Molybdenum), and very inexpensive graphite foil. The CNTs or CFs growth can be achieved using catalyst assisted MPECVD (microwave plasma enhanced chemical vapor deposition) or HFCVD (hot filament chemical vapor deposition) or thermal chemical vapor deposition processes. As such, the contact resistance can also be minimized.

There are two different and distinct configurations possible:

(a) Planar CNTs, CFs: In this configuration, the CNTs and CFs are present as a continuous film on the entire substrate or over the region of interest; and

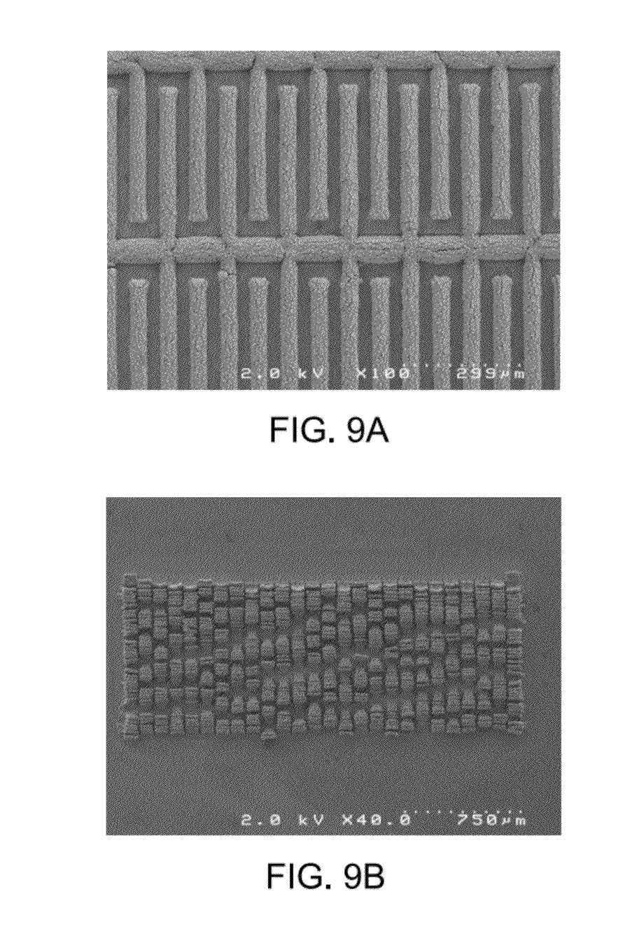

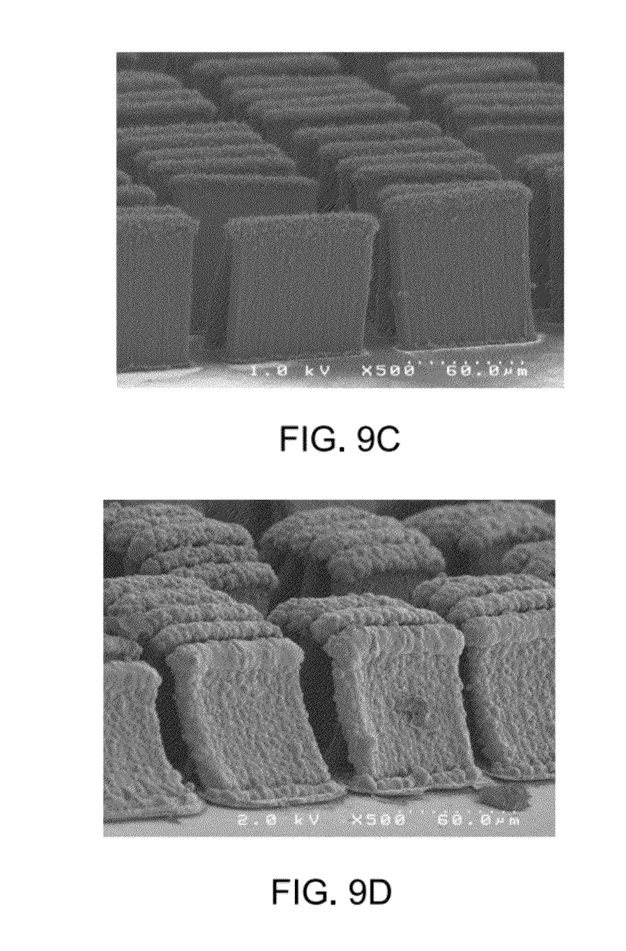

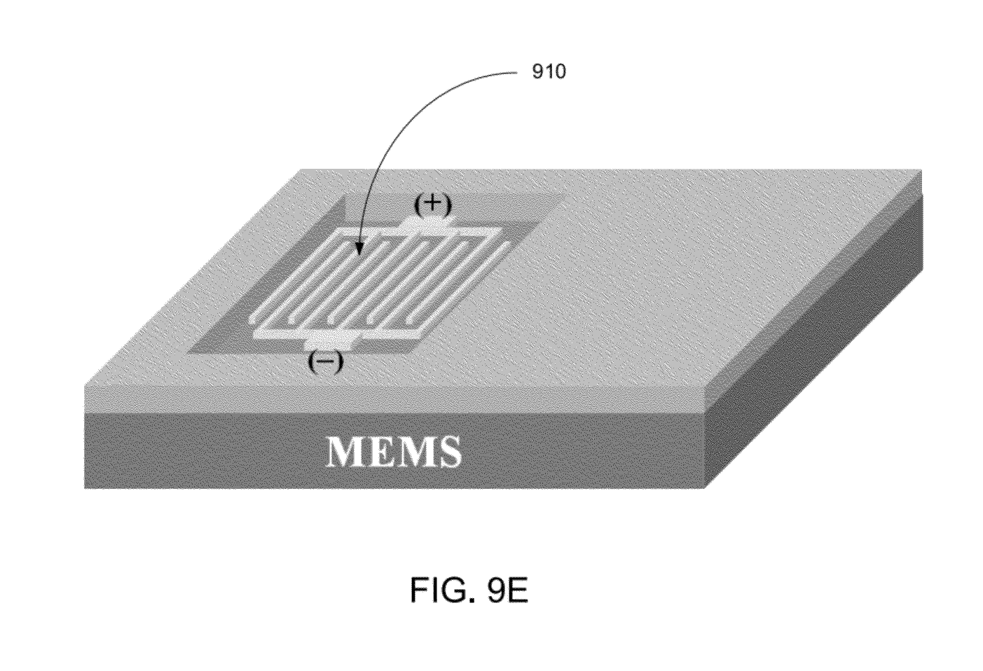

(b) Micropatterned CNT, CF arrays: By using conventional silicon microfabrication technology, pre-determined array patterns are created on the silicon substrates. The individual array element can be circular, square or rectangular, other geometrical shapes and is separated from the nearest neighbor by a finite distance, with a thin layer of silicon dioxide providing electrical isolation. After catalyst deposition, vertically aligned CNTs and CFs are grown in selective regions based on the array design. FIGS. 9A and 9B show two array designs of the micropatterned CNT, CF arrays.

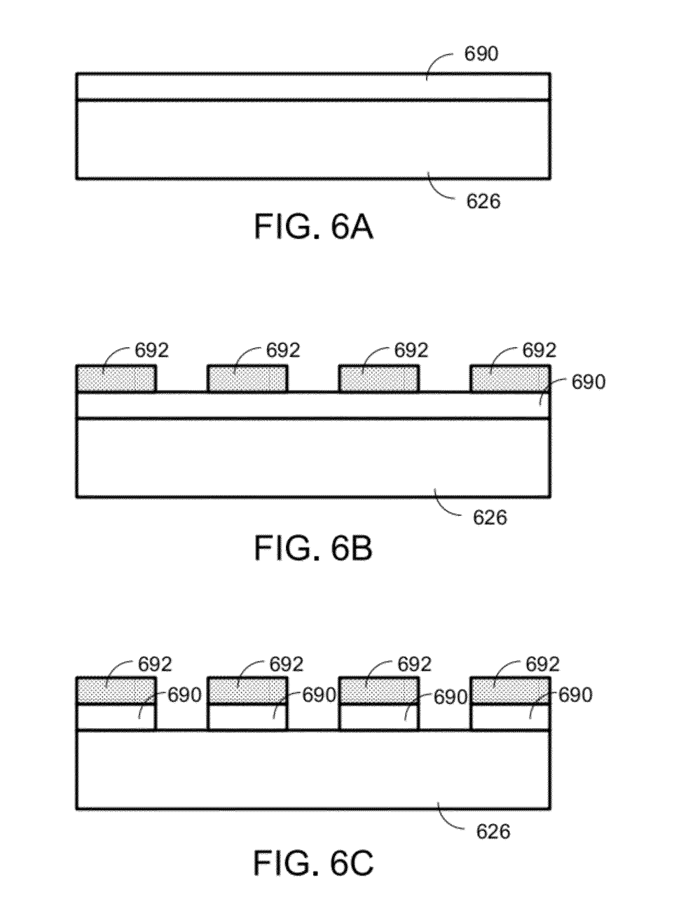

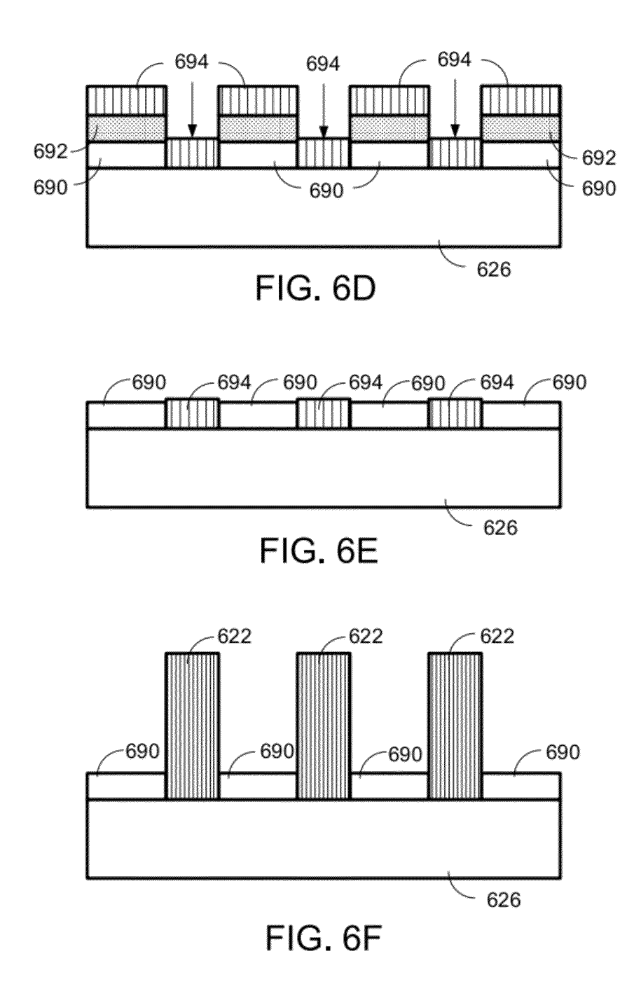

In one embodiment, for the growth of the micropatterned structures of CNTs, a highly doped n-type silicon substrate is thermally oxidized to grow a 0.5 μm thick layer of SiO₂. After spin coating a layer of photoresist, conventional UV photolithography is used to define the outlay of the final structure. This is followed by a wet-etch back of the exposed regions of SiO₂ by BOE solution (buffered oxide etch). Thin layers of titanium (buffer layer) (about 15 nm) and cobalt (catalyst) (about 5 nm) are deposited by DC sputtering technique followed by a photoresist lift-off step. The thickness of the buffer and catalyst layers can be tailored depending upon the CVD process being used for growing CNTs/CFs. Hot filament CVD process is used to grow vertically aligned CNTs in regions where the Ti/Co layers are present. Alternative processes such as thermal CVD or MPECVD can also be used to grow the CNTs/CFs. The SiO₂ layer acts as an insulator to provide isolation between regions where CNTs had been grown. The schematic process of the growth of the micropatterned structures of CNTs is illustrated in FIGS. 6A-6F.

As shown in FIG. 6A, a doped n-type substrate 626 is provided, and an isolation layer 690 is formed on the surface of the substrate 626. The isolation layer 690 can be any isolating material, such as SiO₂ or other isolating materials. In one embodiment, oxidizing the silicon substrate 626 can obtain the SiO₂ layer 690. Next, a photoresist layer 692 is formed on the isolation layer 690, for example, by spin-coating, and then the photoresist layer 690 is patterned to expose regions of the SiO₂ layer, as so to define a patterned layout, as shown in FIG. 6B. The patterned layout is designed such that the exposed areas of the SiO₂ layer 690 are corresponding to the pre-determined array of the first nanostructures. The photoresist layer 692 can be formed using ultraviolet photolithography.

Then, an etching process is performed on the exposed regions of the SiO₂ layer 690 so as to expose the corresponding regions of the silicon substrate, in accordance with the pre-determined array pattern, as shown in FIG. 6C. The etching process can be wet etching, or any other proper etching processes or material removal process.

After the etching process, a buffer layer 694 is deposited in the corresponding exposed regions of the silicon layer, which are corresponding to the array of the first nanostructures, as shown in FIG. 6D. The buffer layer 694 can be formed by a sputtering process, and may include materials such as titanium or a catalyst of cobalt to assist the formation of the vertically aligned carbon nanotubes or carbon nanofibers in later processes.

As shown in FIG. 6D, the buffer layer 694 is also formed on the photoresist layer 692. A removal process is then performed to remove the photoresist layer 692 and the buffer layer 694 formed thereon, as shown in FIG. 6E. Thus, the isolation layer 690 is exposed.

Finally, an MPECVD (microwave plasma enhanced chemical vapor deposition) process or a HFCVD (hot filament chemical vapor deposition) or thermal chemical vapor deposition process is used to grow vertically aligned CNTs or CFs 622 in the regions at which the buffer layer 694 are present so as to form the array of the vertically aligned CNTs or CFs 622 on the substrate 626 in accordance with the pre-determined array pattern, as shown in FIG. 6F. Accordingly, it is achievable that diameters of the CNTs or CFs are in the range of about 1.0-1,000 nm.

As to the formation of the second nanostructures, various methods can be used to provide nano-particles of the active material with the array of the first nanostructures.

After the growth of the current collectors, e.g., CNTs or CFs, on the substrate, an active material (pseudocapacitive material) such as MnO₂ is attached to the CNTs or CFs. The process is extremely important according to the invention, because it requires optimum attachment of the active material to the current collectors. If it is added in excess, then the ultracapacitor/device impedance increases. If it is added less, then one cannot maximize the capacitance obtainable from such a device.

According to the invention, two processes are utilized for the pseudocapacitive material attachment or incorporation. One is a dripping process, which is shown in FIG. 7A according to one embodiment of the present invention. This method is implemented by using a suspension of MnO₂. The suspension is made in two different liquid media, for example, acetone and water. It should be noted that the active material used in FIG. 7A is MnO₂ to form the suspension, but the active material can be silver oxide, iron sulfide, RuO₂, NiOₓ, CoOₓ, V₂O₅ or mixtures thereof, or any other pseudocapacitive materials.

At first, the active material, MnO₂, is prepared, for example, from reduction of KMnO₄ which is a strong oxidizing agent. MnO₂ nanoparticle precipitates are then collected to obtain MnO₂ powder.

In one embodiment, the MnO₂ powder is added into acetone and ultra-sonicated to form a uniform suspension 710. The MnO₂/acetone suspension is then dripped onto CNT thin film formed on the substrate 726 and dried at room temperature to form the CNT/MnO₂ ultracapacitor.

In another embodiment, the MnO₂ powder is added into DI-water, and ultra-sonicated to form the uniform suspension 710. The MnO₂/acetone suspension is then dripped onto CNT thin film formed on the substrate 726 and dried at greater than about 75° C. to form the CNT/MnO₂ ultracapacitor.

The substrate 726 can be a flexible conducting plate on which the CNTs or CFs are formed. In one embodiment, the substrate 726 is disposed on a feeding machine such that the dripping and drying process can be performed by feeding the substrate 726 forward in a direction, as shown in FIG. 7A. Accordingly, a controlled amount of MnO₂ nanoparticles, suspended in acetone or water droplets, can be provided, and it is achievable that the sizes/diameters of the nano-particles of the active material MnO₂ are in the range of 1.0-1000.0 nm.

FIGS. 7B and 7C show SEM images of attachments of MnO₂ onto CNTs by five and ten drops of MnO₂ on CNTs, respectively. FIG. 7D is a transmission electron microscopy (TEM) image showing the CNT and MnO₂ nanoparticles coated thereon.

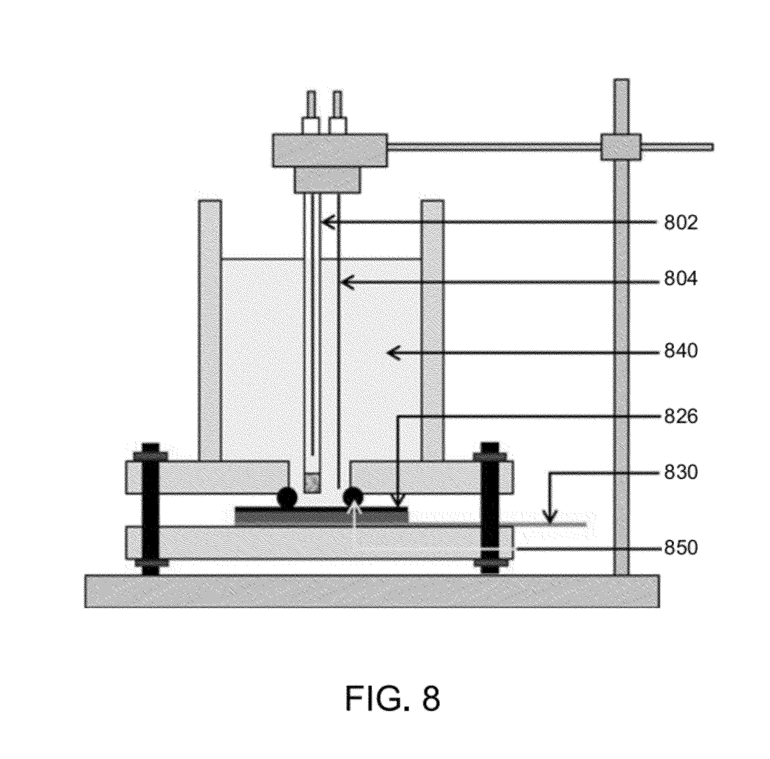

The other process for the pseudocapacitive material incorporation is in-situ electrodeposition of MnO₂ on the current collectors, which is shown in FIG. 8 according to one embodiment of the present invention. In this process, an aqueous solution of KMnO₄, potassium permanganate, is used and MnO₄⁻ is directly reduced to MnO₂ on the CNTs and CFs surface.

KMnO₄ is a strong oxidizing agent. However, it can be electrochemically reduced directly on the conducting substrate by the following reaction.

MnO₄⁻+2H₂O+3e⁻→MnO₂+4OH⁻

Thus, the improvement in the capacitance of the MnO₂/CNT electrode structure can be achieved due to the intercalation/deintercalation of the electrolyte cations in the bulk of the MnO₂.

MnO₂+K⁺e⁻ [symbol] MnOOK

As shown in FIG. 8, the substrate 826 having the array of the first nanostructures is provided on an electrodeposition station, where a KMnO₄ solution 840 is provided to be in contact with the substrate 826 having the array of the first nanostructures. As shown in FIG. 8, the electrodeposition station is a 3-electrode configuration, which has two electrodes 802 and 804, and a copper tape 830 and seal O-ring 850 is provided to ensure the safety of the electrodeposition process. Thus, an in-situ electrodeposition process can be performed with the potassium permanganate solution 840 to form the coating of the nano-particles of manganese dioxide with the array of the first nanostructures on the substrate 826.

In one embodiment, cyclic voltammetry is used at room temperature to electrochemically deposit MnO₂ nanoparticles directly on the CNT network grown on a highly doped silicon substrate and flexible graphite foil (substrate) 826.

After clamping the target substrate in the flat cell, 25 ml of 10 mM KMnO₄ solution in de-ionized water was added. The cyclic voltammetry process involved application of a potential scan between −1V to +1V at a scan rate of 100 mV/s. This was repeated after an interval of 120 seconds. The number of repetitions determines the MnO₂ layer thickness. After the electrodeposition, the KMnO₄ solution can be recycled for electrodeposition on other substrates.

Accordingly, a controlled amount of MnO₂ nanoparticles can be provided, and it is achievable that diameters of the nano-particles of the active material are in the range of 1.0-1000.0 nm.

### Example Seven

### Micropatterned Arrays of CNT/MnO₂ Ultracapacitors

Referring to FIGS. 9A-9D, two micropatterned arrays of CNT/MnO₂ ultracapacitor cells are provided according to embodiments of the present invention. At first, a pre-determined CNT, CF array based on the array design is created on a silicon substrate (e.g., FIG. 9C), by the process disclosed in EXAMPLE SIX. The individual array element can be circular, square or rectangular, or other geometrical shapes and is separated from the nearest neighbor by a finite distance, with a thin layer of silicon dioxide providing electrical isolation. MnO₂ is then attached/coated onto the pre-determined CNT, CF array grown on the silicon to form the micropatterned arrays of CNT/MnO₂ ultracapacitor cell, as shown in FIGS. 9A, 9B and 9D.

FIG. 9E shows a MEMS application of a finger-type micropatterned array of CNT/MnO₂ ultracapacitor cell 910.

### Example Eight

### Characterizations of CNT/MnO₂ Ultracapacitor Cells

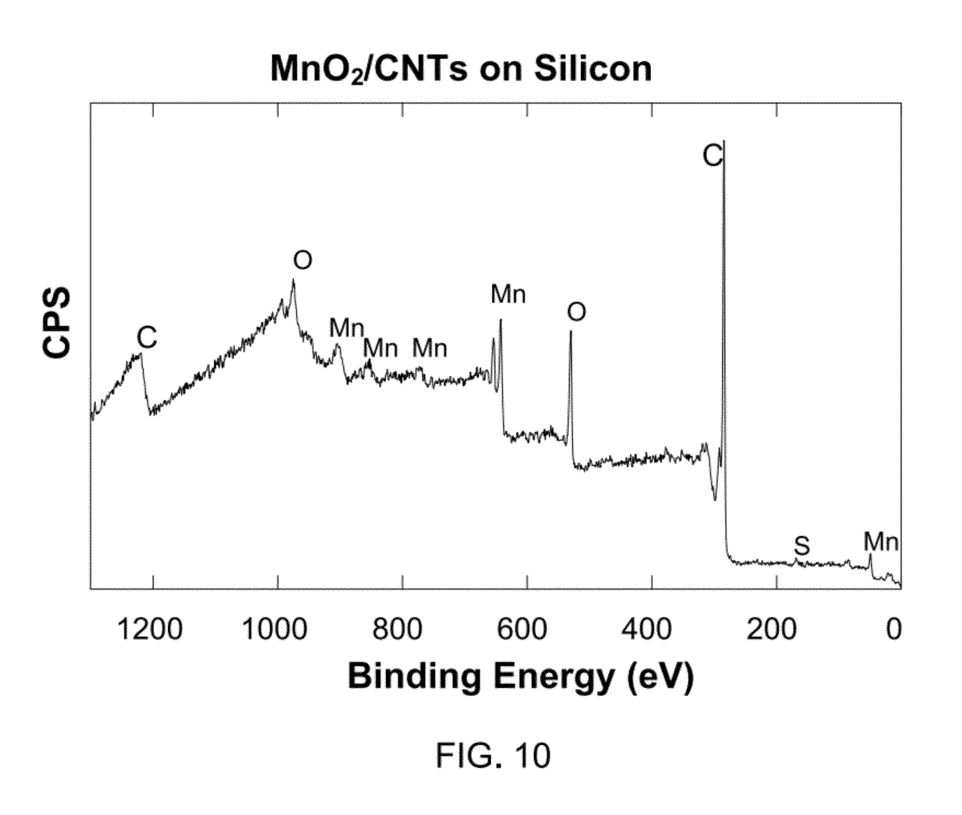

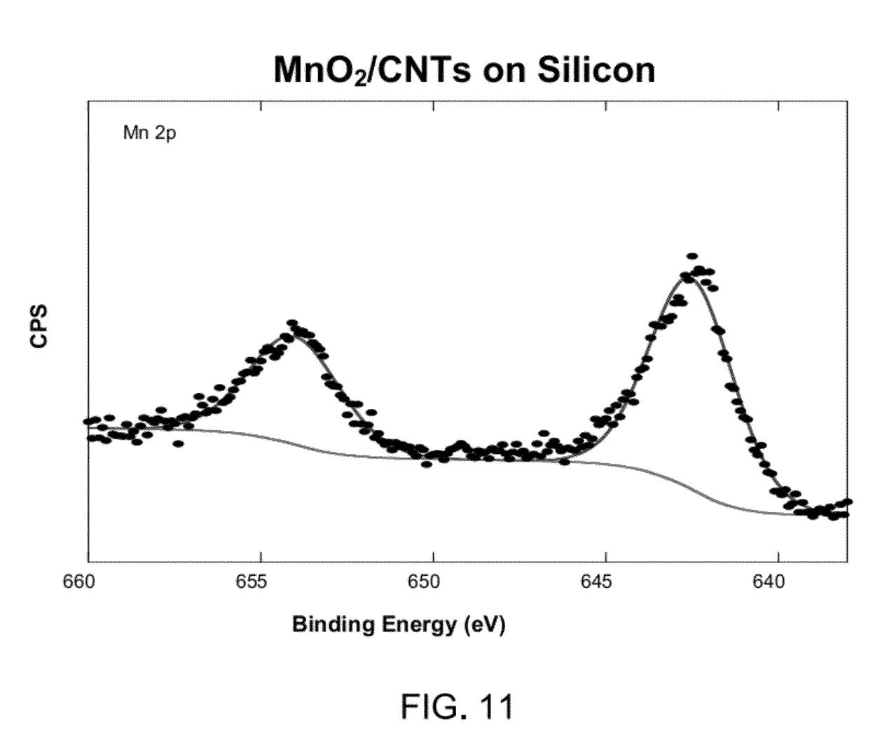

FIGS. 10 and 11 show X-ray photoelectron spectroscopy (XPS) plots of MnO₂ coated CNTs grown on a silicon substrate according to one embodiment of the present invention. As shown in FIGS. 10 and 11, the X-ray photoelectron spectra show binding-energy peaks that confirm the presence of a significant quantity of MnO₂, in which peaks at 653.6 eV (Mn 2p_{1/2}) and 642.2 eV (Mn 2p_{3/2}) correspond to MnO₂ binding energies (as shown in FIG. 11).

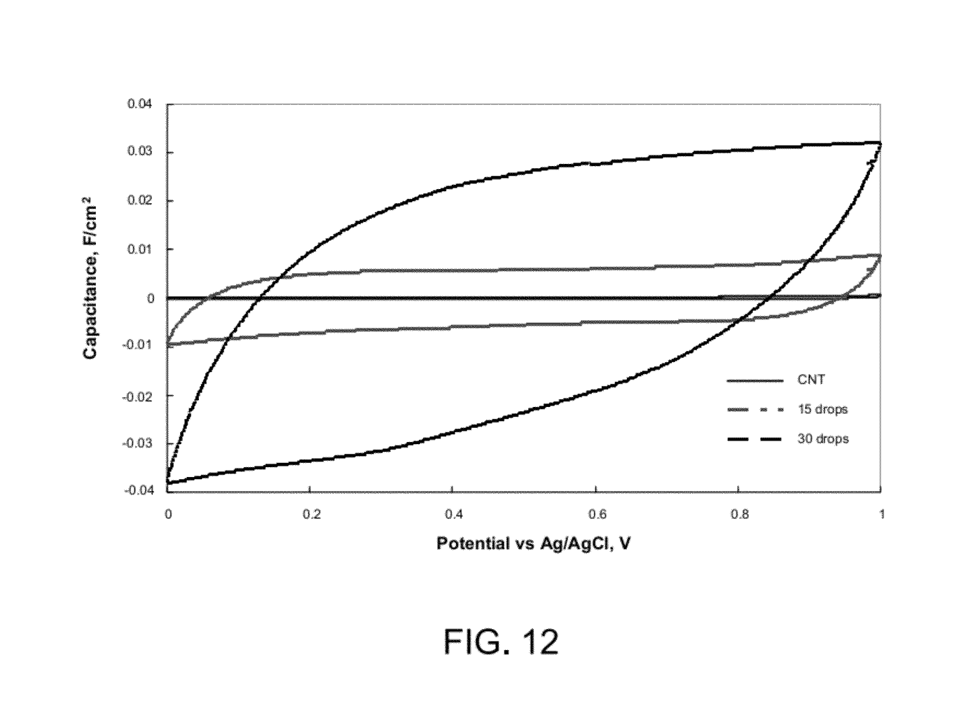

To examine the effect of MnO₂ on the capacitance of CNT electrodes, 5-droplet, 15-droplet, and 30-droplet samples, along with a pristine CNT control sample, are tested as working electrodes in 0.1M KCl electrolyte. FIG. 12 shows a diagram of cyclic voltammograms of CNT and CNT coated with 15 and 30 droplets of MnO₂ according to one embodiment of the present invention. As shown in FIG. 12, the cyclic voltammetry data indicates that both of the CNT/MnO₂ nanocomposite electrodes have significant enhanced capacitance compared to the control CNT electrode and that their capacitances increase as MnO₂ is added.

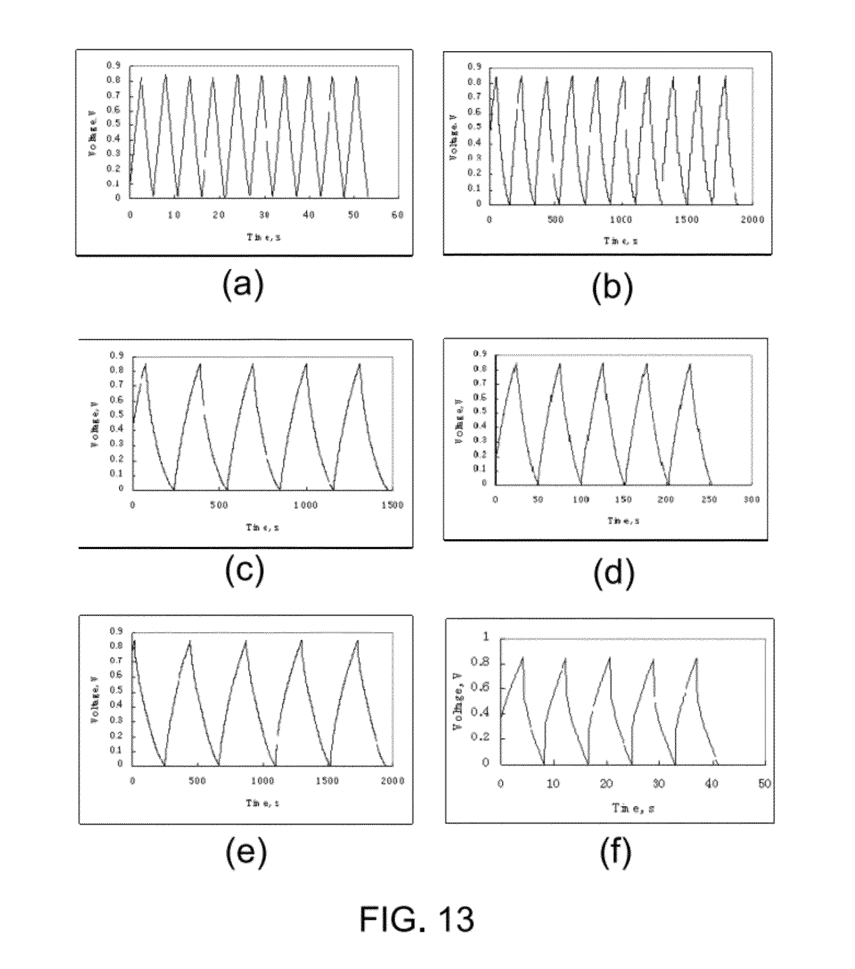

To examine their cyclic stabilities and to further quantify their capacitances, galvanostatic charging-discharging tests were performed. FIG. 13 shows a plurality of diagrams showing galvano-static charging and discharging behavior of (A) as-grown CNT film at 30 μA, (B) 5-droplet sample at 30 μA, (C) 15-droplet sample at 30 μA, (D) 15-droplet sample at 120 μA, (E) 30-droplet sample at 120 μA, and (F) 30-droplet sample at 1920 μA, respectively according to one embodiment of the present invention. Based on the duration of average charging-discharging cycle of each electrode, a 400× improvement in capacitance over that of the plain CNT electrode was observed, demonstrating exceptional capacitance behavior and long-term chemical stability potentially suitable for numerous applications.

In the following examples, four different designs are disclosed for producing MnO₂/CNT based ultracapacitors. The first design is a square array consisting of 25,600 (160×160) circular elements, each of 3 μm diameter and 30 μm spacing (pitch). The second design is of a rectangular array of 858 (33×26) elements, each 75 μm long and 6 μm wide with a spacing of 30 μm. The third design is an inter-digitated structure with fingers 400 μm long and 40 μm wide. Finally, the fourth design is a device including CNTs grown on a flexible substrate, graphite foil (125 μm thick), and then wrapped around a Teflon rod.

In the first design, 25,600 circular elements of CNT structures, each of 3 μm diameter and 30 μm pitch, were arranged in a square array, and 10 μm tall CNTs were grown by a hot filament CVD process. All the CNTs are isolated from each other by the isolation layer of SiO₂. The two electrodes 802 and 804 are Ag/AgCl (3M KCl) (as a reference electrode) and a platinum wire (as a counter electrode). CVs were recorded in 0.1M KCl as the electrolyte at different scan rates (10 mV/s, 50 mV/s, 100 mV/s, 200 mV/s and 500 mV/s), before and after any MnO₂ deposition step.

The CV measurements were taken in a flat cell in a 3 electrode configuration, which is similar to the device shown in FIG. 8. The MnO₂/CNT array/Si was the working electrode, Ag/AgCl (3M KCl) reference electrode and a platinum wire as the counter electrode. CVs were recorded in 0.1M KCl as the electrolyte at different scan rates (10 mV/s, 50 mV/s, 100 mV/s, 200 mV/s and 500 mV/s), before and after any MnO₂ deposition step.

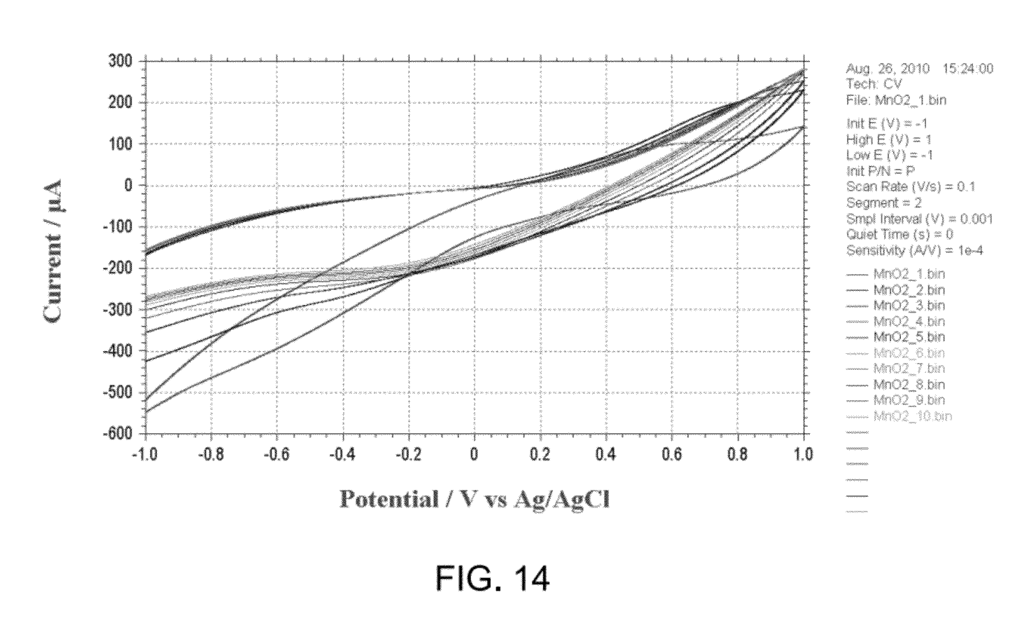

The electrochemical deposition of MnO₂ was done by using cyclic voltammetry in a 10 m M KMnO₄ solution under ambient conditions. The deposition was achieved in 10 cycles (20 sweep segments) with an interval of 60 s between each cycle. CVs recorded during MnO₂ deposition can be seen in FIG. 14, which shows a diagram of CVs recorded during 10 cycles (20 sweep segments) of MnO₂ deposition at 100 mV/s in 10 mM KMnO₄ and potential scan limits of −1V to +1V according to a first design of the present invention. The parameters used are tabulated in the following table.

| | [KMnO₄] | Scan Rate | Scan | Numbers | Numbers | Interval |
|---|---|---|---|---|---|---|
| | (mM) | (mV/s) | Window | of cycles | of steps | between cycles |
| 1 | 10 | 100 | −1 V to + 1 V | 10 | 10 | 60 s |

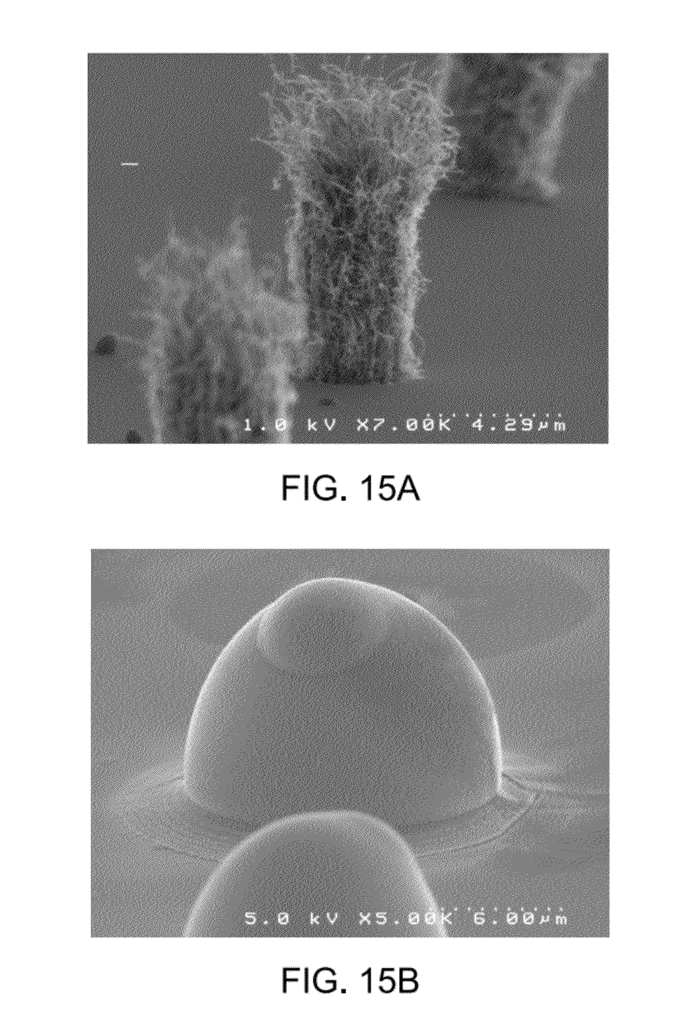

FIG. 15A is a SEM image showing an as-grown CNT array according to one design of the present invention, and FIG. 15B is an SEM image showing the final MnO₂ coated CNT array. As shown in FIG. 15B, MnO₂ formed a conformal thin coating on the vertically aligned CNTs. The post-deposition images show that the 10 cycles produced a very thick coating, localized at the CNT “posts”. From an original CNT “post” size of 3 μm diameter, the final diameter of the MnO₂ coated CNT structure increases to about 12 μm due to a prolific rate of deposition.

The active area based on the CNT footprint will be used for current density measurements and can be calculated as follows:

Total Area=160×160×3.14×(1.5)²×10⁻⁸ cm²=0.00181 cm².

Total volume=0.00181 cm²×10×10⁻⁴ cm=1.81×10⁻⁶ cm³.

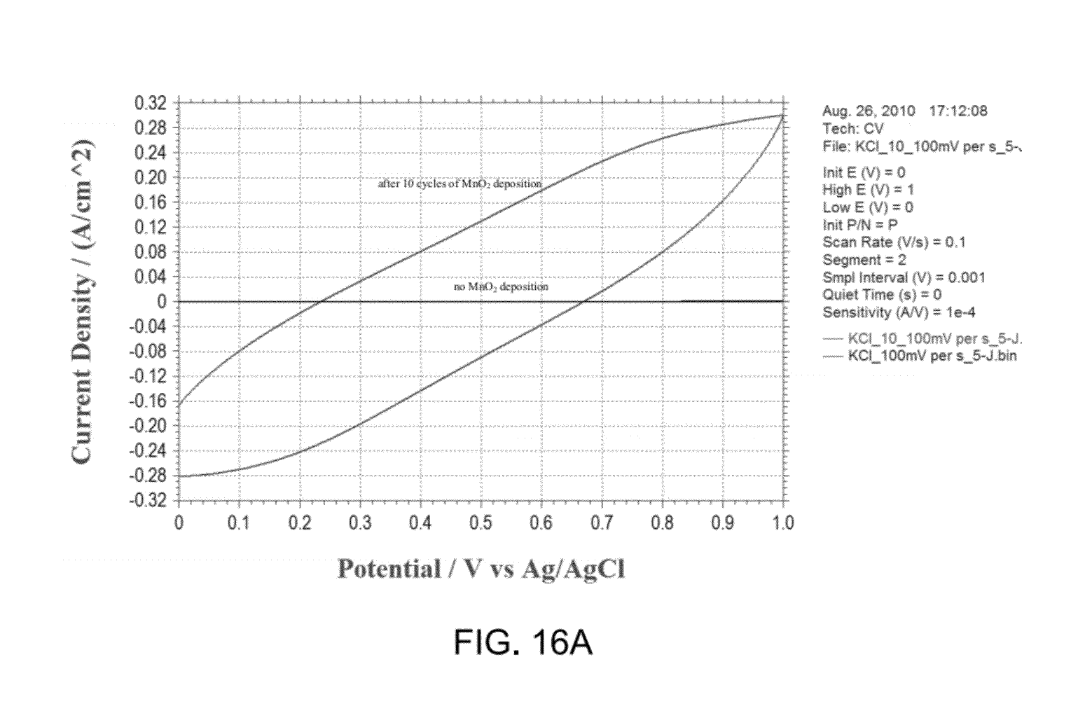

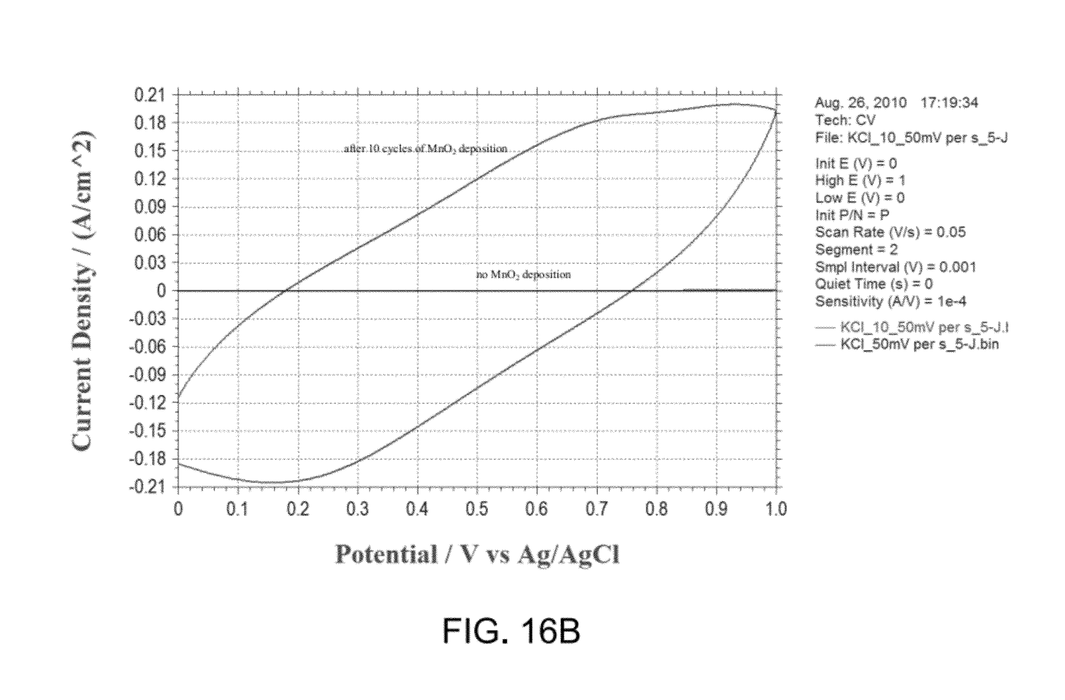

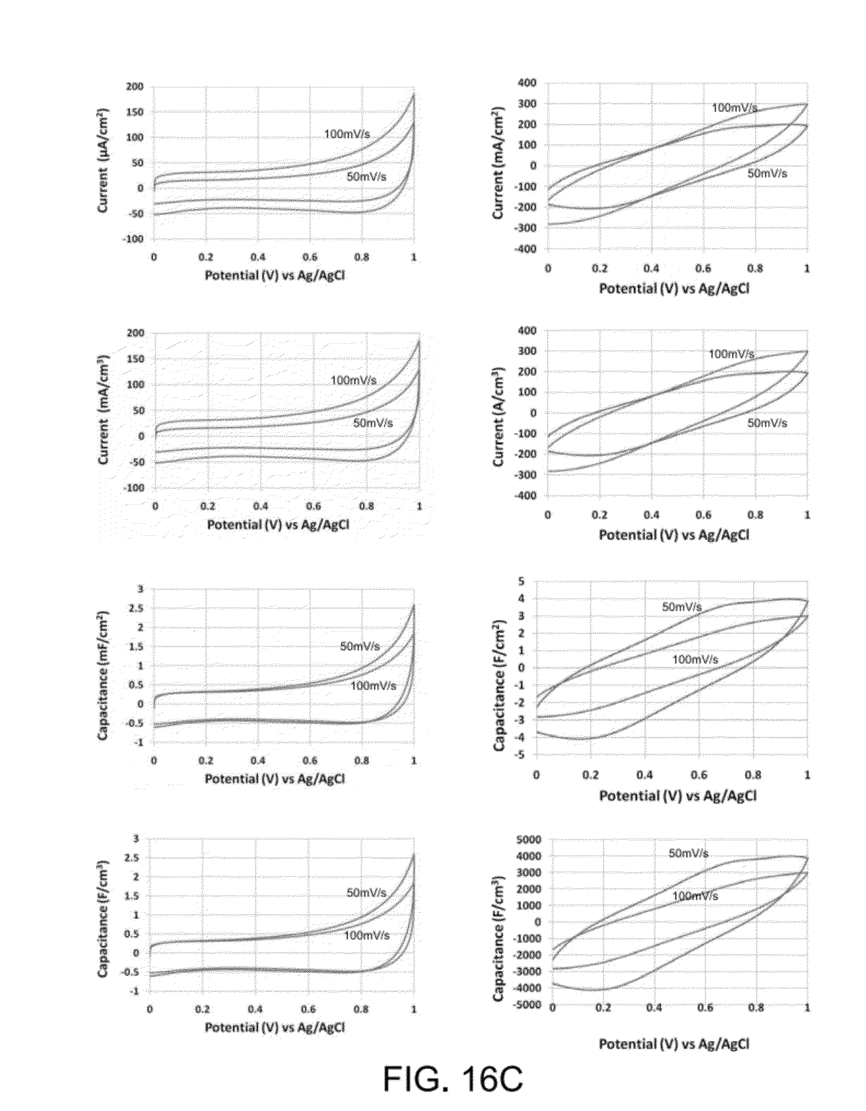

The CVs recorded in 0.1M KCl with and without MnO₂ at 100 mV/s and 50 mV/s scan rate are shown in FIGS. 16A and 16B respectively. FIG. 16A shows a diagram of CVs recorded in 0.1M KCl at 100 mV/s showing the extremely high enhancement in the capacitive currents, and FIG. 16B shows a diagram of CVs recorded in 0.1M KCl at 50 mV/s showing the extremely high enhancement in the capacitive currents. There is an extremely high enhancement in the capacitive currents, almost 2700× at 100 mV/s and 5000× at 50 mV/s, as compared to that observed with no MnO₂. To get a better understanding of the magnitude of this enhancement, a side-by-side comparison of diagrams of CVs recorded in 0.1M KCl before (on the left) and after the deposition steps (on the right) are shown in FIG. 16C. The current-voltage and capacitance-voltage curves have been expressed in areal as well as in volumetric densities.

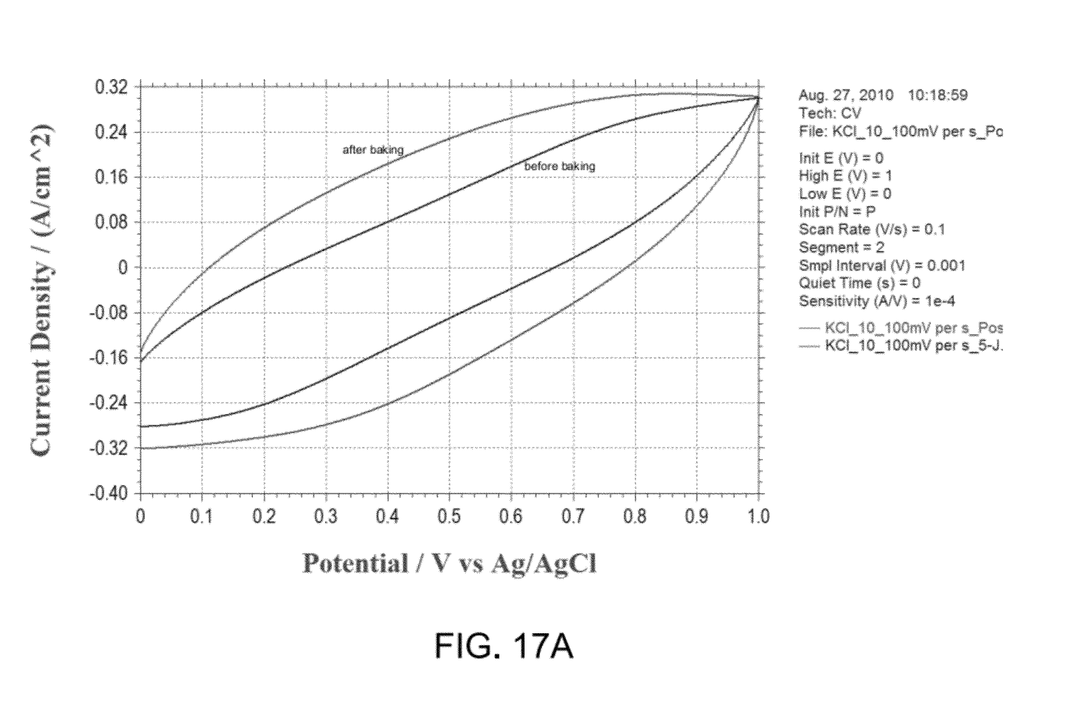

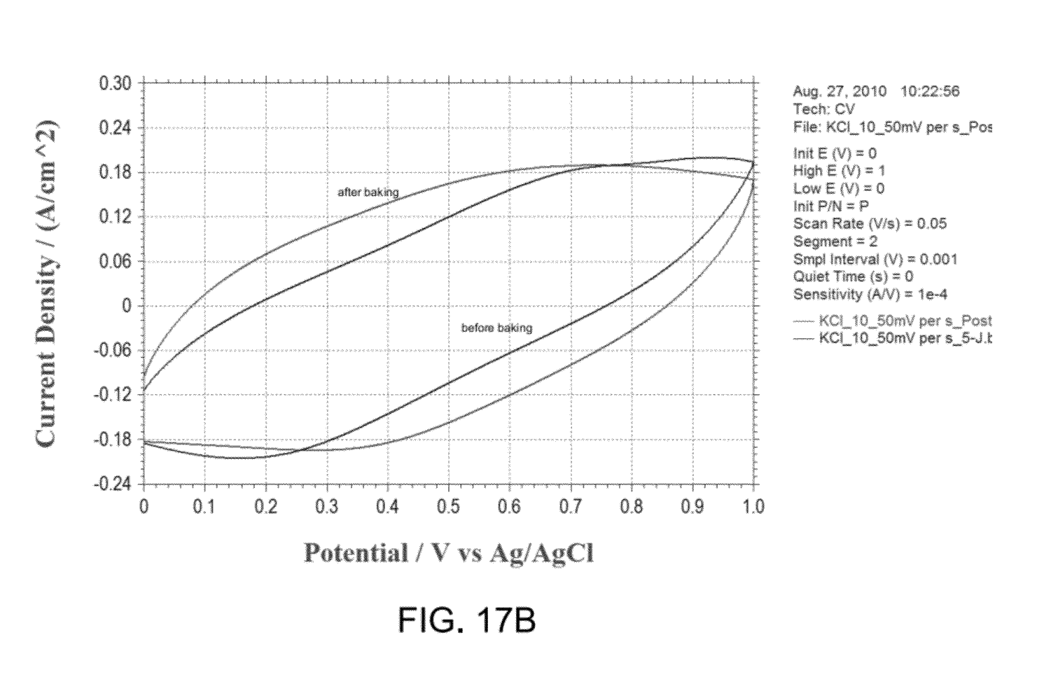

The device in the first design was also baked at 100° C. for 1 hour under ambient conditions after the 10 cycles of MnO₂ deposition. FIG. 17A shows a diagram of CVs recorded in 0.1M KCl at 100 mV/s showing almost 2 times enhancement in the capacitive currents after baking at 100° C. for 1 hour, and FIG. 17B shows a diagram of CVs recorded in 0.1M KCl at 50 mV/s showing almost 1.4 times enhancement in the capacitive currents after baking at 100° C. for 1 hour. As shown in FIGS. 17A and 17B, an improvement in the response was observed, almost 2 times at 100 mV/s and 1.4 times at 50 mV/s.

The second design was of a rectangular array of 858 (33×26) elements, each 75 μm long and 6 μmwide with a spacing of 30 μm. 75 μm tall CNTs were grown by hot filament CVD process, as shown in FIG. 9C. All the CNT “walls” are isolated from each other by the isolation layer of SiO₂.

The CV measurements were taken in a flat cell in a 3 electrode configuration, which is similar to the device shown in FIG. 8. The MnO₂/CNT array/Si was the working electrode, Ag/AgCl (3M KCl) reference electrode and a platinum wire as the counter electrode. CVs were recorded in 0.1M KCl as the electrolyte at different scan rates (10 mV/s, 50 mV/s, 100 mV/s, 200 mV/s and 500 mV/s), before and after any MnO₂ deposition step.

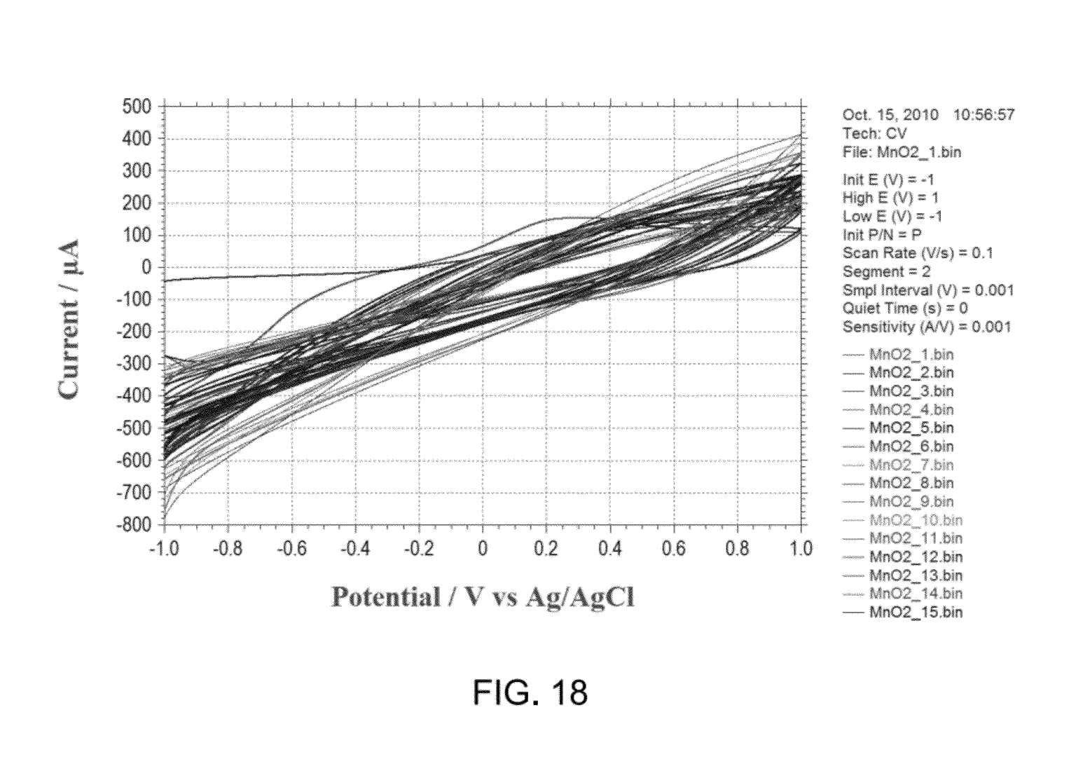

The electrochemical deposition of MnO₂ was done by using cyclic voltammetry in a 10 mM KMnO₄ solution under ambient conditions. The deposition was achieved in 15 sets of 2 cycles each (4 sweep segments) for a total of 30 cycles with an interval of 120 s between each cycle. CVs recorded during MnO₂ deposition (#30) is shown in FIG. 18, which shows a diagram of CVs recorded during 30 cycles (60 sweep segments) of MnO₂ deposition at 100 mV/s in 10 mM KMnO₄ and potential scan limits of −1V to +1V according to a second design of the present invention. The parameters used are tabulated in the following table.

| | [KMnO₄] | Scan Rate | Scan | Numbers | Numbers | Interval |
|---|---|---|---|---|---|---|
| | (mM) | (mV/s) | Window | of cycles | of steps | between cycles |
| 2 | 10 | 100 | −1 V to +1 V | 30 | 2 | 120 s |

The active area based on the CNT footprint will be used for current density measurements and can be calculated as follows:

Total Area=33×26×75×10⁻⁴×6×10⁻⁴ cm²=0.00386 cm².

Total volume=0.00386 cm²×75×10⁻⁴ cm=2.9×10⁻⁵ cm³.

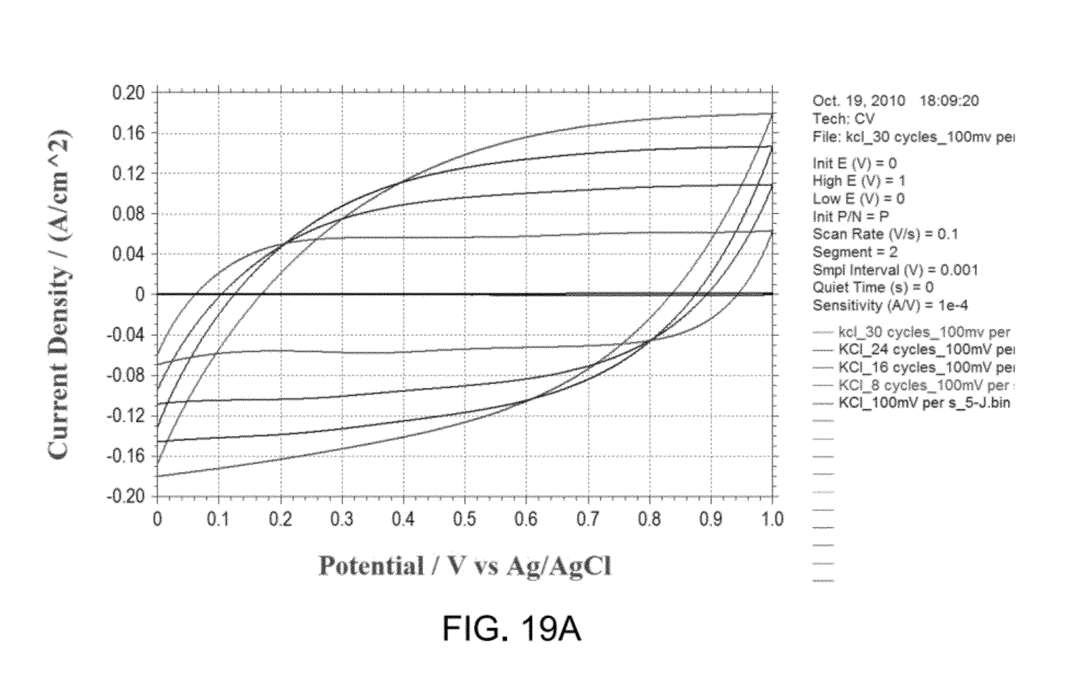

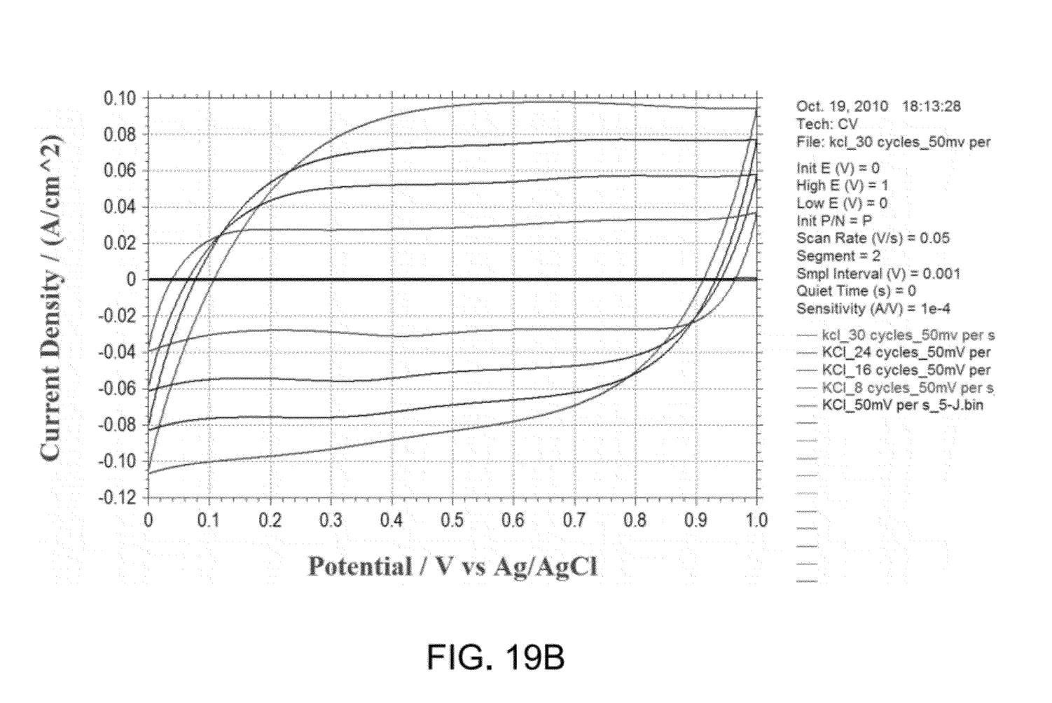

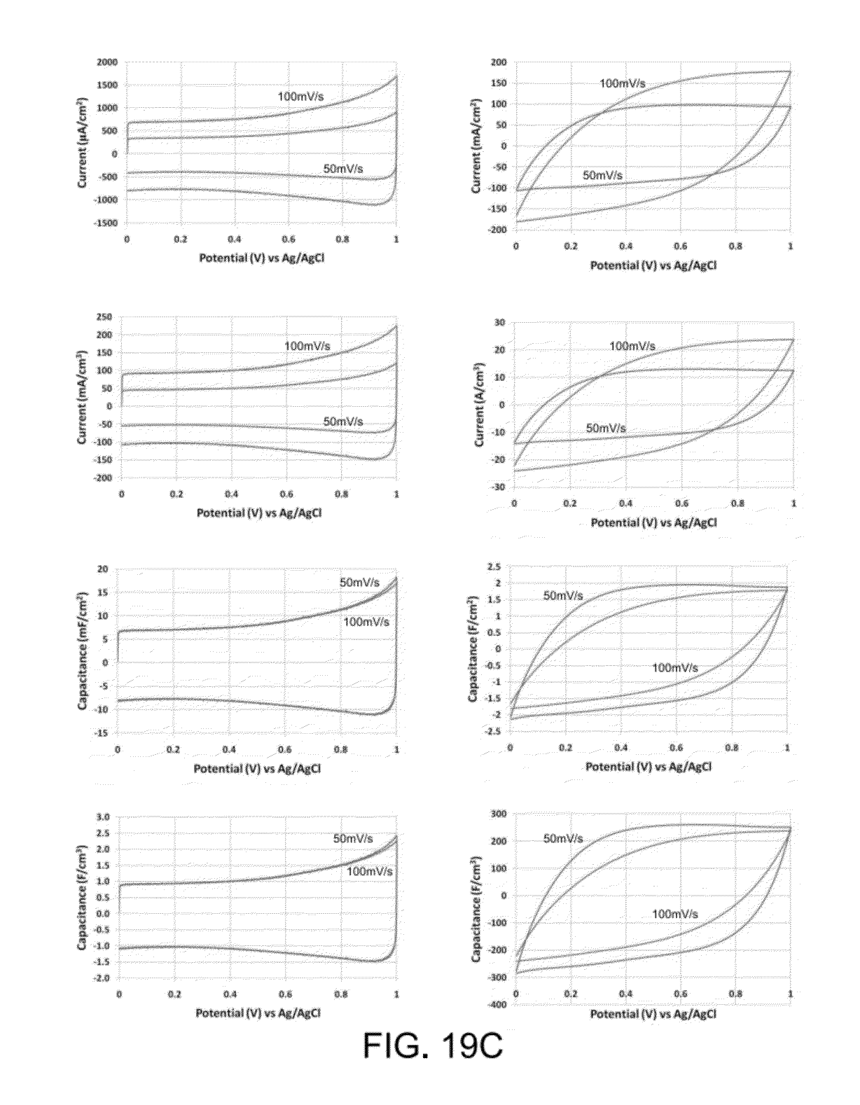

CVs recorded in KCl before MnO₂ deposition and after 8, 16, 24 and 30 cycles of MnO₂ deposition at 100 mV/s and 50 mV/s scan rates are shown in FIGS. 19A and 19B respectively. FIG. 19A shows a diagram of CVs recorded in 0.1M KCl at 100 mV/s showing the extremely high enhancement in the capacitive currents, and FIG. 19B shows a diagram of CVs recorded in 0.1M KCl at 50 mV/s showing the extremely high enhancement in the capacitive currents. The data recorded after the remaining deposition cycles have been omitted to provide more clarity. A side-by-side comparison of CVs recorded in 0.1M KCl before (on the left) and after the deposition steps (on the right) are shown in FIG. 19C. The current-voltage and capacitance-voltage curves have been expressed in areal as well as in volumetric densities. The MnO₂/CNT ultracapacitor exhibits high capacitance values while retaining a rectangular shape.

The third design was of interdigitated electrodes with each finger 400 μm long and 40 μm wide and having a gap of 40 μm between the fingers. The fingers of each electrode are connected by an 80 μm wide “path”. 25 μm tall CNTs were grown by hot filament CVD process, as shown in FIG. 9A. The interdigitated electrodes were isolated from each other by the SiO₂ layer.

The CV measurements were taken in a flat cell in a 3 electrode configuration, which is similar to the device shown in FIG. 8. The MnO₂/CNT array/Si was the working electrode, Ag/AgCl (3M KCl) reference electrode and a platinum wire as the counter electrode. CVs were recorded in 0.1M KCl as the electrolyte at different scan rates (10 mV/s, 50 mV/s, 100 mV/s, 200 mV/s and 500 mV/s), before and after any MnO₂ deposition step.

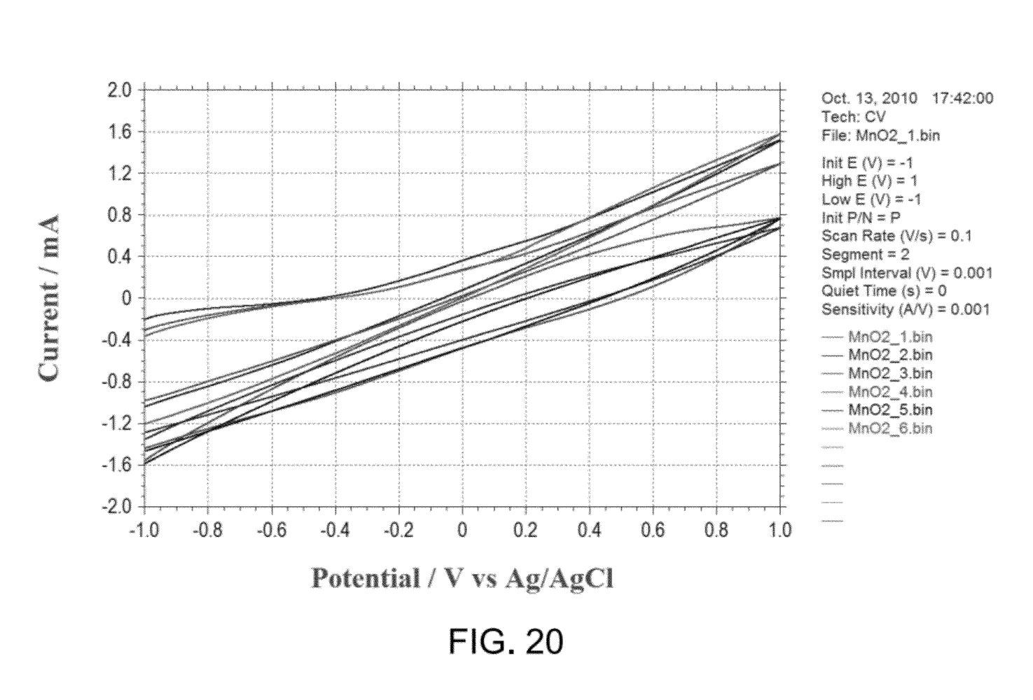

The electrochemical deposition of MnO₂ was done by cyclic voltammetry in a 10 mM KMnO₄ solution under ambient conditions. The deposition was achieved in 3 sets of 2 cycles each (4 sweep segments) for a total of 6 cycles with an interval of 120 s between each cycle. CVs recorded during MnO₂ deposition is shown in FIG. 20, which shows a diagram of CVs recorded during 10 cycles (20 sweep segments) of MnO₂ deposition at 100 mV/s in 10 mM KMnO₄ and potential scan limits of −1V to +1V according to a second design of the present invention. It should be noted that even though the structure consisted of 2 interdigitated electrodes, they were used as one, in combination, by providing an electrical contact on the back side of the silicon substrate. The parameters used are tabulated in the following table.

| | [KMnO₄] | Scan Rate | Scan | Numbers | Numbers | Interval |
|---|---|---|---|---|---|---|
| | (mM) | (mV/s) | Window | of cycles | of steps | between cycles |
| 3 | 10 | 100 | −1 V to +1 V | 6 | 2 | 120 s |

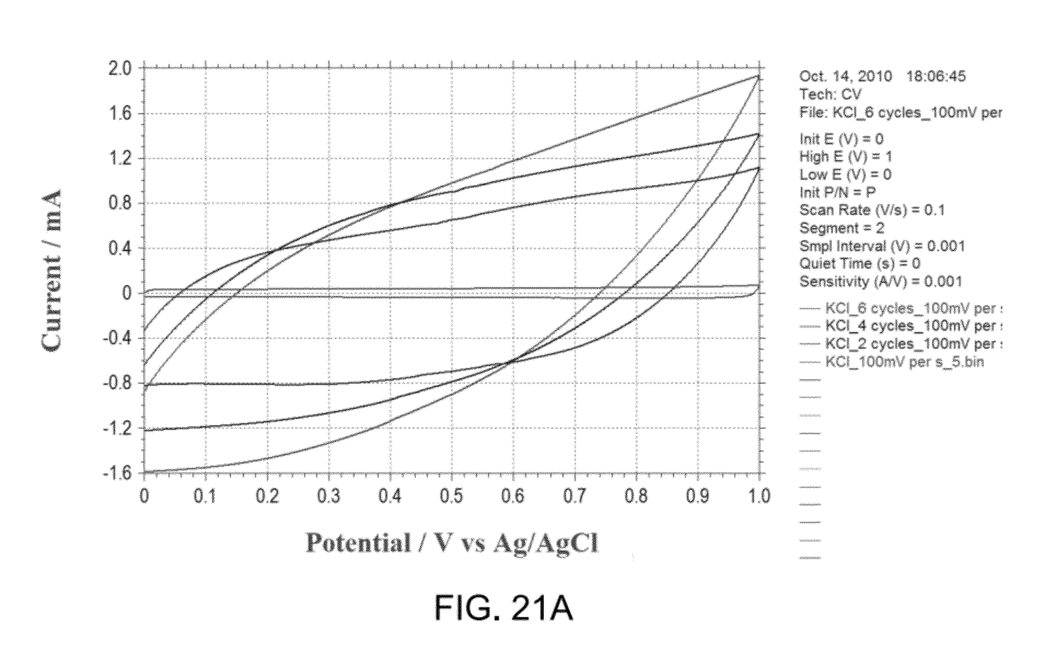

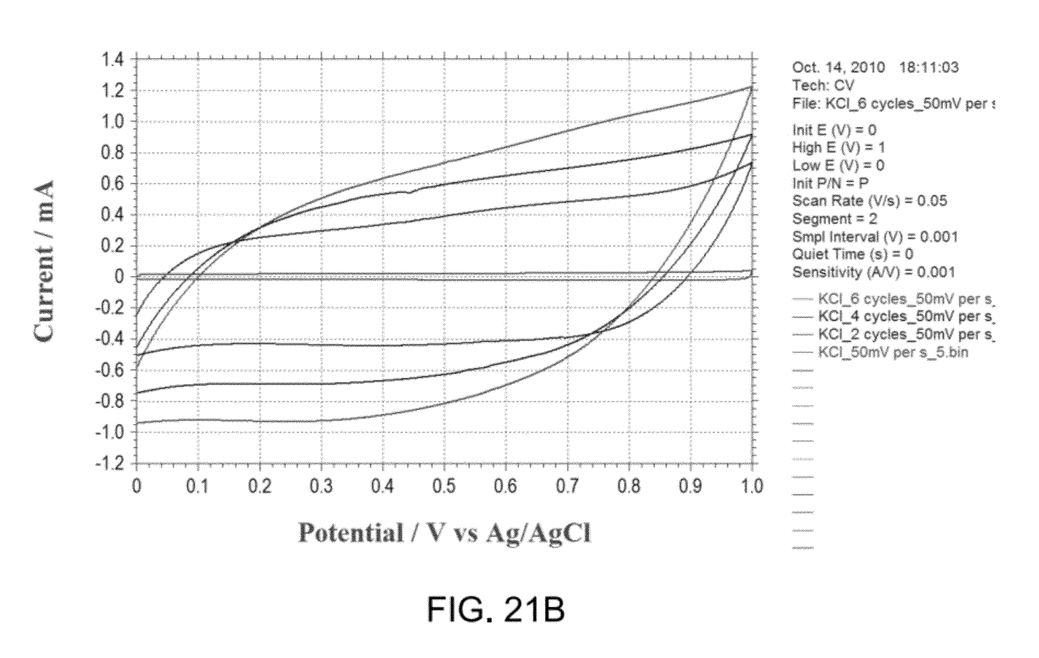

CVs recorded in KCl after 2, 4 and 6 cycles of MnO₂ deposition at 100 mV/s and 50 mV/s scan rates are shown in FIGS. 21A and 21B respectively. FIG. 21A shows a diagram of CVs recorded in 0.1M KCl at 100 mV/s showing the extremely high enhancement in the capacitive currents, and FIG. 21B shows a diagram of CVs recorded in 0.1M KCl at 50 mV/s showing the extremely high enhancement in the capacitive currents. The CVs recorded before MnO₂ depositions have also been included for comparison. There is a consistent increase in the capacitive currents with increase in MnO₂ thickness.

The fourth design was of a device consisting of CNTs grown on a flexible substrate, graphite foil (125 μm thick), and then wrapped around a Teflon rod. The dense CNT forest was grown using hot-filament CVD process.

The CV measurements were taken in a flat cell in a 3 electrode configuration, which is similar to the device shown in FIG. 8. The MnO₂/CNT array/Graphite was the working electrode, Ag/AgCl (3M KCl) reference electrode and a platinum wire as the counter electrode. CVs were recorded in 0.1M KCl as the electrolyte at different scan rates (10 mV/s, 50 mV/s, 100 mV/s, 200 mV/s and 500 mV/s), before and after any MnO₂ deposition step.

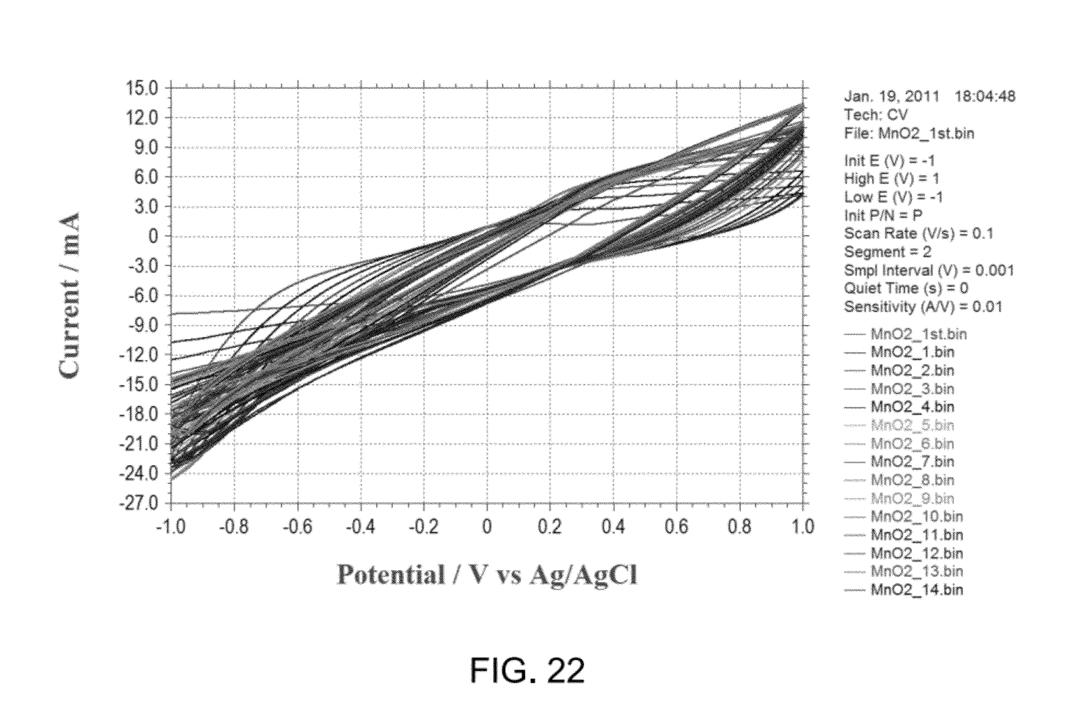

The deposition was achieved in 2 sets, one of 30 cycles (60 sweep segments) and the second of 10 cycles (20 sweep segments) for a total of 40 cycles with an interval of 120 s between each cycle. CVs recorded during MnO₂ deposition are shown in FIG. 22. The parameters used are tabulated in the following table.

| | [KMnO₄] | Scan Rate | Scan | Numbers | Numbers | Interval |
|---|---|---|---|---|---|---|
| | (mM) | (mV/s) | Window | of cycles | of steps | between cycles |
| 4 | 10 | 100 | −1 V to +1 V | 30 | 1 | 120 s |
| 4 | 10 | 100 | −1 V to +1 V | 10 | 1 | 120 s |

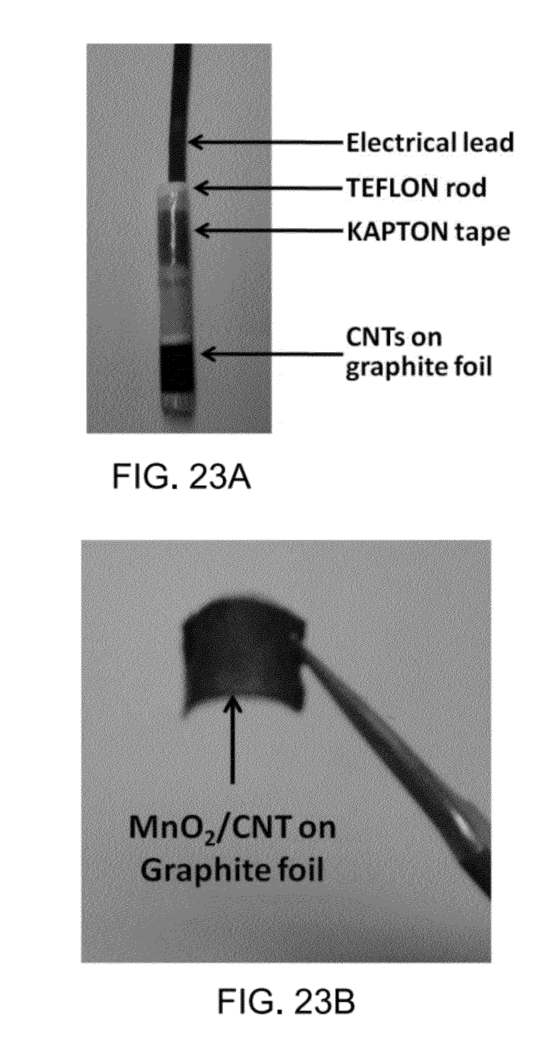

The assembly used to perform the capacitance measurements and MnO₂ deposition is shown in FIG. 23A. CNT on graphite foil was wrapped around a Teflon rod and electrical connectivity was provided by a strip of graphite foil. Kapton tape was used on back side of the graphite foil and the exposed electrical lead to prevent any access to the KMnO₄ solution. The final MnO₂/CNT/Graphite structure after detaching it from the Teflon rod is shown in FIG. 23B.

The active area based on the CNT footprint will be used for current density measurements and can be calculated as follows:

Total Area=1×1.2 cm²=1.2 cm².

Total volume=1.2 cm²×3×10⁻⁴ cm=3.6×10⁻⁴ cm³.

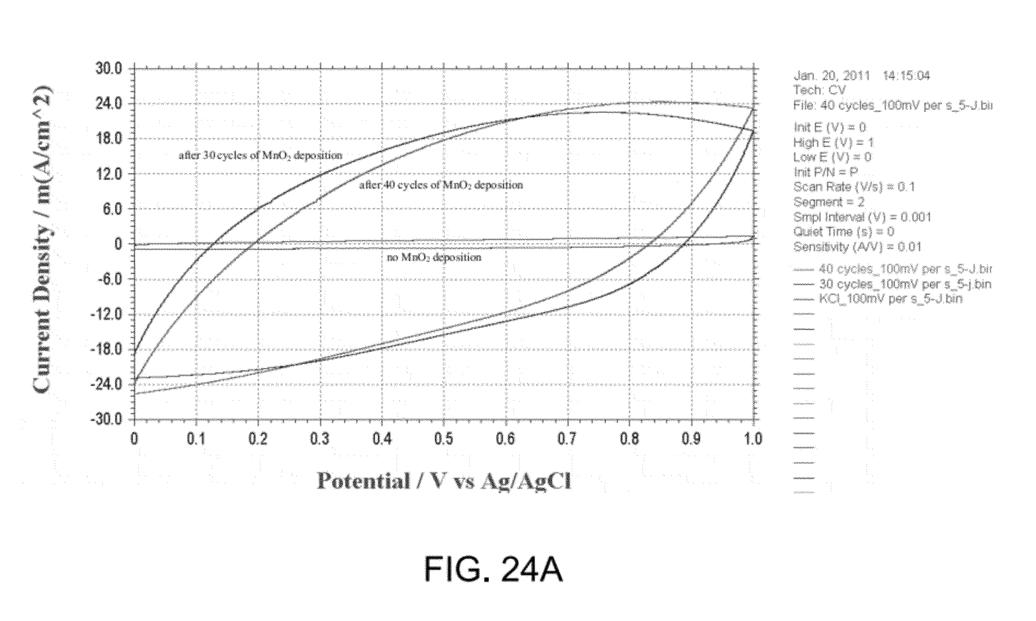

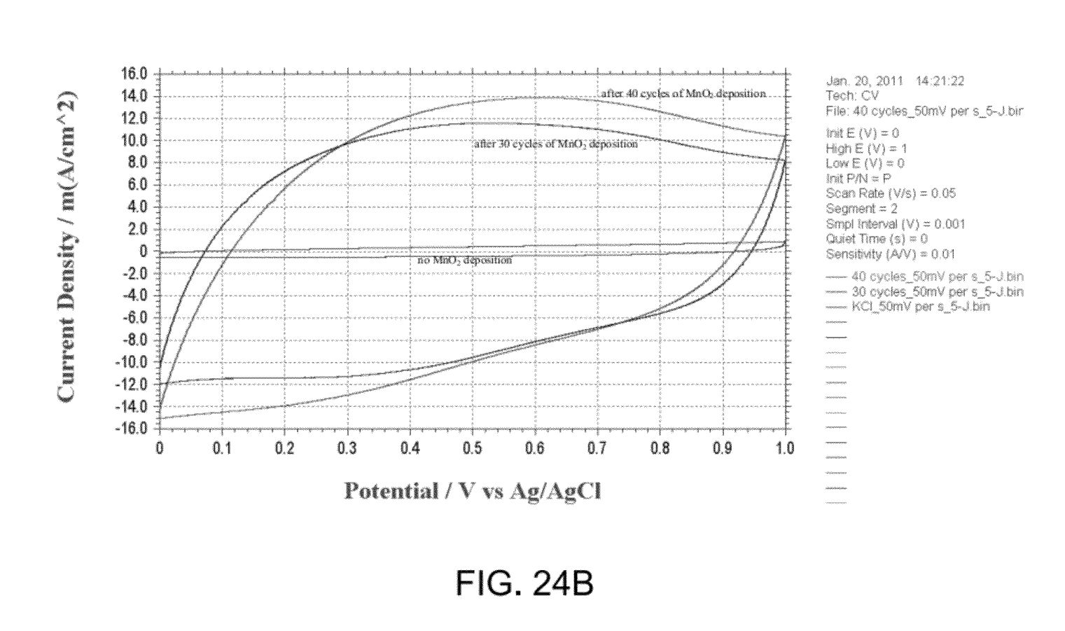

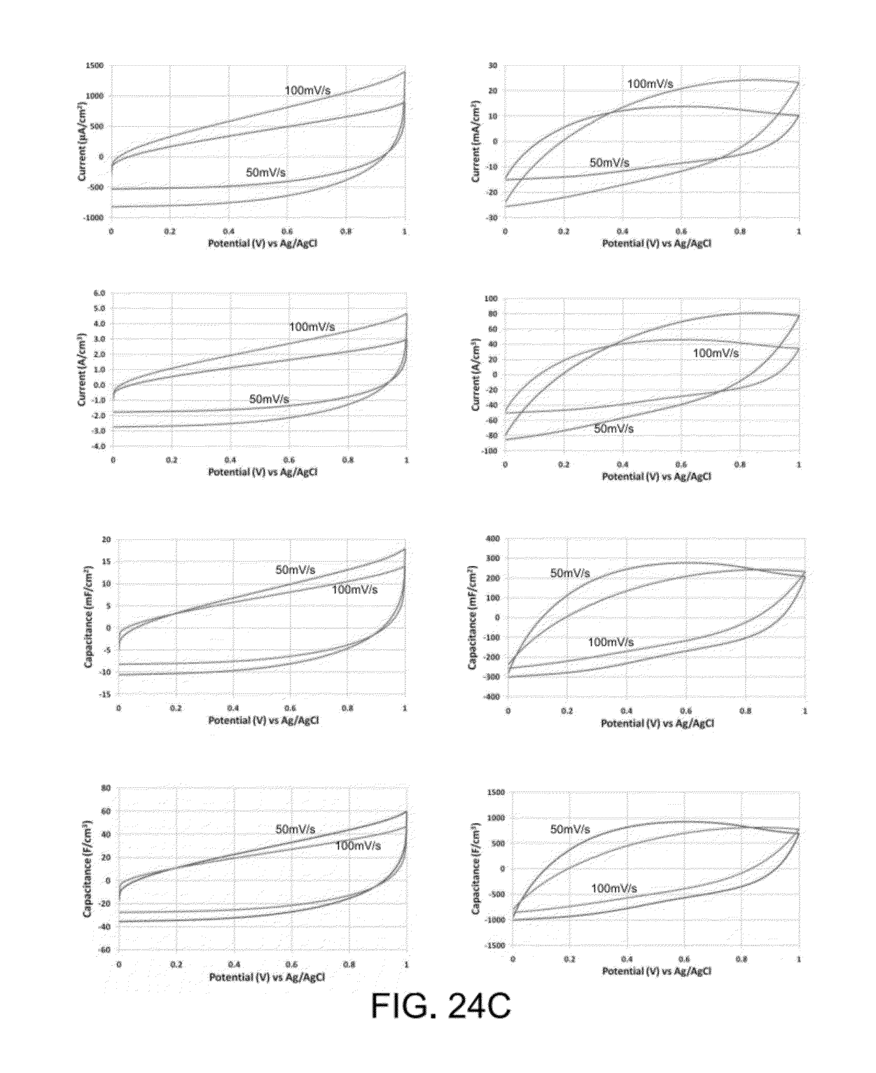

The CVs recorded in 0.1M KCl after 40 cycles, 30 cycles and without MnO₂ at 100 mV/s and 50 mV/s scan rate are shown in FIGS. 24A and 24B respectively. FIG. 24A shows a diagram of CVs recorded in 0.1M KCl at 100 mV/s showing the extremely high enhancement in the capacitive currents, and FIG. 24B shows a diagram of CVs recorded in 0.1M KCl at 50 mV/s showing the extremely high enhancement in the capacitive currents. The capacitive currents are greatly enhanced due to 30 cycles of MnO₂ deposition. There is not much improvement in the response after further deposition. To get a better understanding of the magnitude of this enhancement, a side-by-side comparison of CVs recorded before (on the left) and after the deposition steps (on the right) is shown in FIG. 24C. The current-voltage and capacitance-voltage curves have been expressed in areal as well as in volumetric densities.

In sum, the present invention provides, among other things, a novel hybrid electrochemical ultracapacitor that combines desirable attributes such as extremely high energy-power density, excellent life-cycle reliability and safety characteristics, with low production cost and has the potential for widespread deployment in energy delivery/storage applications. According to the present invention, CNTs or CFs were grown directly on conducting flexible (or rigid) substrates to reduce contact resistances, and the more controllable CNT or CF nanoarchitectures for optimum attachment of inexpensive pseudocapacitive MnO₂ nanoparticles to enhance charge efficiency and energy-power capacity was exploited. The approach employs “green” electrolyte that increases cell voltage. Accordingly, a specific capacitance of the CNT/MnO₂ electrode 100-1000 times higher than as-grown CNT-only thin-film electrodes and >50× larger energy density than conventional electrochemical capacitors is achieved. With further optimization of electrode configurations and cell voltage, it is expected to further increase the specific capacitance and maximize energy-power, achieving a transformational energy storage/delivery system both fundamentally and technologically.

Among other things, the advantages of the present invention are (a) better control of CNT growth on supporting substrate, including flexible conducting foils, (b) enhanced application of the MnO₂ nanoparticles, and (c) progress in the choice of large-scale fabrication techniques. The technology is robust and easily integrated into all types of energy storage/delivery applications. It is demonstrated that this technology is amenable to simple and ‘foldable’ packaging which supports the prototypes cell described herein. The prototypes made according to various embodiments of the present invention described can be easily integrated into many applications, including high-voltage applications in which numerous ultracapacitors are configured into parallel-connected stacks or banks.

A further benefit of this technology is that it utilizes completely benign materials such that damage, destruction and disposal are each inconsequential and environmentally neutral. The novel ultracapacitor technology is scalable in performance.

Moreover, the diversity and flexibility in design and material selections allow an electrochemical ultracapacitor to cover a broad range of power vs. energy plot, and bridge the performance gap between the high power densities offered by conventional capacitors and high energy densities of batteries. The push to obtain higher energy without sacrificing power is the central focus of electrochemical ultracapacitor research. Ruthenium dioxide (RuO₂) has attracted much attention as a suitable component for CNT composite due to its outstanding pseudocapacitance and excellent reversibility, but the low availability and extremely high cost limit its practical use. Moreover, it is an environmentally hazardous material. On the other hand, active materials such as MnO₂ are inexpensive, readily available, environmentally friendly, and demonstrates good pseudocapacitance behavior.

The described invention for achieving extreme high energy and power density ultracapacitor is based on symmetric cell design, but is also applied to asymmetric cell design as well. The ultracapacitor utilizes an advanced nanoarchitectured pseudocapacitive electrode to enhance energy density with a 3D nanostructured high-surface-area CNT conductor electrode for optimum pseudocapacitive MnO₂ nanoparticle impregnation, and ionic electrolyte to operate with greater cell voltage. When charging, the positive cations in the electrolyte are attracted to the negative electrode, and the negative anions to the positive electrode. Both negative and positive ions in the electrolyte accumulate at the electrode surface to compensate for the electronic charge. Hence, electrical energy is stored inside the electrochemical double layer (the Helmholtz layer) at the electrode-electrolyte interface. This effect is further enhanced by the fast reversible redox faradaic pseudocapacitance induced by the MnO₂ nanoparticles. The thickness of the double layer (varies between 5 and 10 angstroms) is usually determined by the electrolyte concentration and the ion size. Since capacitance is proportional to the electrode area, C=εA/d, higher capacitance can be obtained by making electrodes from nanostructured CNT for attachment of the nanoscaled MnO₂ to optimize the pseudocapacitive effect with very large effective surface areas.

Using the innovative nanostructuring approach realized in the ultracapacitor of the present invention, MnO₂ has been incorporated directly onto the surface of CNTs carpet by a simple liquid media (‘dripping’) method. In such a configuration, the CNT surface serves as high-surface-area, 3D current collector for MnO₂ coatings, and defines the electrode's internal pore structure to facilitate the infiltration and rapid transport of electrolyte to the nanoscopic MnO₂. Although such 3D CNT/MnO₂ nanostructures can still being further optimized, results by practicing the present invention indicate this approach is far superior to other electrochemical ultracapacitor approaches as per the Ragone curve, >50× in energy density. The experiment results according to the present invention also predict that efficient utilization of the incorporated MnO₂ phase can achieve >2,000 F/g. Furthermore, based on the experimental results according to the present invention and the electrochemical ultracapacitor theory, using an asymmetric cell configuration and ionic liquid with cell voltage of ˜3V, the projected performance of the hybrid ultracapacitor of the present invention may far exceed the power-energy density provided by the battery technology.

The preliminary accomplishments of the present invention can be, among other things, highlighted below:
The novel CNT/MnO₂ hybrid ultracapacitor of the present invention is 100-1,000× better than ultracapacitor based on CNTs alone. It has >50× larger energy density than conventional ultracapacitor. Further improvements would be expected by optimizing MnO₂ impregnation on CNT forest.
By practicing the present invention, it has been achieved about 700 F/g and are on track to achieve >2000 F/g.
The power density of the present invention is currently 5000-6000 W/kg compared to 50-400 W/kg for conventional batteries and 1000 W/kg for conventional ultracapacitors. It is expected further improvements (such as to distribute MnO₂ nano-particles throughout the CNT forest) can enhance the performance. Both the direct growth of conducting CNTs on the supporting substrate and direct impregnation of MnO₂ on CNT reduce ESR and hence improve power density. The nascent ESR of the present invention is nominally much less than 1 ohm, exceptionally low at the low frequencies needed for energy storage. The CNT/MnO₂/electrolyte system of the present invention has no mechanism for, and thus is not subject to, drying out or corroding. The operating cycles of the present invention have shown no ESR increase with time, no degradation with cycling, and little change with temperature variation.
The energy density of the present invention is currently 20 Wh/kg compared to 0.1-2 Wh/kg for conventional ultracapacitors. The energy density will scale directly with the device capacitance (as further noted below).
It has achieved extremely high capacitance density of 1 F/cm², (or volumetric capacitance >200 F/cm³, or >200 J/cc at 1V) by practicing the present invention. Moreover, we have recently obtained exceedingly high volumetric capacitance ˜1,000 F/cm³, using cylindrical configuration, the highest value reported to date.
The approach of the present invention is scalable in performance due to tremendous flexibility with respect to form factor. This will permit stacking of capacitors in just about any configuration desired. One should be able to meet any electrical specifications requirements and any reasonable space constraints consistent with the power and energy densities achieved by practicing the present invention. It is compact and lightweight.
The device of the present invention has lifetimes and reliabilities that match or exceed currently available ultracapacitors. Cycle life stability of >95% demonstrated. Fast charging/discharging time (minute) compared to (hours) for batteries.
Large-scale fabrication can be achieved through the use of well-established thin film micro-fabrication, CNT synthesis, and electrochemical cell packaging technologies. The final ultracapacitor cell can be integrated into any existing energy system.
The fabrication cost in practicing the present invention is lower than conventional ultracapacitors. In one embodiment of the present invention, one synthesizes CNTs directly on inexpensive conducting substrate (commercial flexible graphite foil), and energy-efficient CVD (simple thermal excitation). Preliminary estimates indicate the material-cost of this ultracapacitor technology is less than half that of other energy storage media such as lithium-based systems or rare-earth composites. Most importantly, a cost-effective and environmental friendly method for preparation and attachment of low cost (‘dirt’ cheap) MnO₂ nanoparticles onto the CNT 3D framework by a simple dripping/wetting method has been successfully demonstrated.
The ultracapacitor technology of the present invention is much safer and more environmentally friendly than battery technology. The technology utilizes completely of non-toxic materials, such that operation, damage, destruction, and disposal are each inconsequential and environmentally neutral. Finally, full-scale production will also be safe and ‘green’.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. An ultracapacitor, comprising:
(a) a first plate;
(b) a second plate; and
(c) a separator sandwiched between the first plate and the second plate,
wherein each of the first plate and the second plate comprises:
a substrate;
first nanostructures formed on the substrate; and
second nanostructures, being different from the first nanostructures, attached to the first nanostructures.

2. The ultracapacitor of claim 1, wherein the substrate comprises a doped silicon substrate.

3. The ultracapacitor of claim 1, wherein the substrate comprises a rigid conducting substrate.

4. The ultracapacitor of claim 1, wherein the substrate comprises a flexible conducting substrate.

5. The ultracapacitor of claim 4, further comprising one or more insulation layers disposed on at least one of the first plate and the second plate, wherein rolling over the ultracapacitor defines a cylindrical-type multi-layered ultracapacitor cell.

6. The ultracapacitor of claim 1, wherein the first nanostructures comprise carbon nanotubes (CNTs) or carbon fibers/nanofibers (CFs), wherein the CNTs or CFs are grown on the substrate.

7. The ultracapacitor of claim 6, wherein the CNTs or CFs have diameters or thicknesses in a range of about 1.0-1,000.0 nm.

8. The ultracapacitor of claim 6, wherein the first nanostructures are grown in a continuous film on the entire substrate or over the region of interest of the substrate.

9. The ultracapacitor of claim 6, wherein the first nanostructures are grown in a pre-determined array pattern on the substrate.

10. The ultracapacitor of claim 1, wherein the second nanostructures comprise nano-particles of an active material, having diameters or sizes in a range of about 1.0-1000.0 nm.

11. The ultracapacitor of claim 10, wherein the active material comprises MnO₂, Ag₂O, FeS, RuO₂, NiOₓ, CoOₓ, V₂O₅ or a mixture thereof.

12. The ultracapacitor of claim 1, wherein the separator is porous.

13. The ultracapacitor of claim 1, wherein the first plate and the second plate are adapted to be symmetrical or asymmetrical.

14. The ultracapacitor of claim 1, further comprising an electrolyte solution filled in spaces among the first nanostructures and the second nanostructures in each of the first plate and the second plate.

15. An electrical energy storage device, comprising at least one ultracapacitor claimed in claim 1, wherein the first plate and the second plate are formed with materials and with dimensions such that the specific capacitance is greater than 500 F/g.

16. An ultracapacitor cell, comprising:
a plurality of ultracapacitors electrically parallel-connected to each other,
wherein each ultracapacitor comprises:
(a) a first plate;
(b) a second plate; and
(c) a separator sandwiched between the first plate and the second plate,
wherein each of the first plate and the second plate comprises:
a substrate;
first nanostructures formed on the substrate; and
second nanostructures, being different from the first nanostructures, attached to the first nanostructures.

17. The ultracapacitor cell of claim 16, further comprising a first conducting track member and a second conducting track member positioned apart from the first conducting track member to define a space therebetween, wherein the plurality of ultracapacitors is stacked in the space and parallel-connected through the first and second conducting track members.

18. The ultracapacitor cell of claim 16, wherein the first nanostructures comprise carbon nanotubes (CNTs) or carbon fibers/nanofibers (CFs), wherein the CNTs or CFs are grown on the substrate.

19. The ultracapacitor cell of claim 18, wherein the first nanostructures are grown in a continuous film on the entire substrate or over the region of interest of the substrate.

20. The ultracapacitor cell of claim 18, wherein the first nanostructures are grown in a pre-determined array pattern on the substrate.

21. The ultracapacitor cell of claim 16, wherein the second nanostructures comprise nano-particles of an active material, wherein the active material comprises MnO₂, Ag₂O, FeS, RuO₂, NiOₓ, CoOₓ, V₂O₅ or a mixture thereof.

22. The ultracapacitor cell of claim 16, wherein the separator is porous.

23. The ultracapacitor cell of claim 16, further comprising an electrolyte solution filled in spaces among the first nanostructures and the second nanostructures in each of the first plate and the second plate.

24. An ultracapacitor cell, comprising:
(a) a first conducting track member and a second conducting track member positioned apart from the first conducting track member to define a space therebetween;
(b) a plurality of first plates electrically coupled to the first conducting track member;
(c) a plurality of second plates electrically coupled to the second conducting track member, wherein the plurality of first plates and the plurality of second plates are alternately positioned in the space defined between the first conducting track member and the second conducting track member; and
(d) a plurality of separators, wherein each separator is sandwiched between a respective first plate and its adjacent second plate in the space,
wherein each of the plurality of first plates and the plurality of second plates comprises a conducting substrate, first nanostructures formed on the conducting substrate, and second nanostructures, being different from the first nanostructures, attached to the first nanostructures formed on the conducting substrate.

25. The ultracapacitor cell of claim 24, wherein the first nanostructures comprise carbon nanotubes (CNTs) or carbon fibers/nanofibers (CFs), wherein the CNTs or CFs are grown on the substrate.

26. The ultracapacitor cell of claim 24, wherein the second nanostructures comprise nano-particles of an active material.

27. The ultracapacitor cell of claim 24, wherein each separator is porous.

28. A method of fabricating an ultracapacitor, comprising the steps of:
(a) forming a first plate and a second plate, wherein each of the first and second plates comprises:
a substrate;
first nanostructures formed on the substrate; and
second nanostructures, being different from the first nanostructures, attached to the first nanostructures; and
(b) disposing a separator between the first plate and the second plate.

29. The method of claim 28, wherein the substrate comprises a rigid conducting substrate or a flexible conducting substrate.

30. The method of claim 28, wherein the step of forming each of the first plate and the second plate comprises the steps of:
(a) growing the first nanostructures on the substrate; and
(b) attaching the second nanostructures to the first nanostructures grown on the substrate;
wherein the first nanostructures comprises carbon nanotubes (CNTs) or carbon fibers (CFs).

31. The method of claim 30, wherein the first nanostructures are grown in a continuous film on the entire substrate or over the region of interest of the substrate.

32. The method of claim 30, wherein the first nanostructures are grown in a pre-determined array pattern on the substrate.

33. The method of claim 32, wherein the substrate comprises a doped n-type silicon substrate, wherein the growing step comprises the steps of:
(a) oxidizing the silicon substrate to form a layer of SiO₂ on the silicon substrate;
(b) spin-coating a layer of photoresist on the SiO₂ layer;
(c) patterning the photoresist layer to expose regions of the SiO₂ layer in accordance with the pre-determined array pattern;
(d) wet-etching back of the exposed regions of the SiO₂ layer to expose the corresponding regions of the silicon substrate;
(e) depositing a buffer layer in the corresponding exposed regions of the silicon layer;
(f) lifting off the photoresist on the SiO₂ layer; and
(g) growing CNTs or CFs in the regions at which the buffer layer are present so as to form the array of the vertically aligned CNTs or CFs on the substrate in accordance with the pre-determined array pattern.

34. The method of claim 33, wherein the buffer layer comprises a thin layer of metal, including titanium.

35. The method of claim 34, wherein the buffer layer comprises a catalyst of a thin layer of metal, including cobalt.

36. The method of claim 33, wherein the growing step is performed with an MPECVD (microwave plasma enhanced chemical vapor deposition) process or a HFCVD (hot filament chemical vapor deposition) process or thermal chemical vapor deposition process.

37. The method of claim 30, wherein the second nanostructures comprise nano-particles of an active material, and wherein the active material comprises of pseudocapacitive material, such as MnO₂.

38. The method of claim 37, wherein the attaching step comprises the steps of:
(a) preparing a suspension of the nano-particles of the active material in a liquid medium;
(b) dripping the suspension into the first nanostructures grown on the substrate; and
(c) drying the suspension to attach the nano-particles of the active material onto the first nanostructures.

39. The method of claim 38, wherein the liquid medium comprises acetone or water or other liquid media.

40. The method of claim 37, wherein the attaching step comprises the steps of:
(a) providing a solution containing KMnO₄ and water; and
(b) performing in-situ electrodeposition of the solution in the CNTs or CFs grown on the substrate so as to impregnate MnO₂ on the CNTs or CFs.

41. The method of claim 28, further comprising the step of filling an electrolyte solution in spaces among the first nanostructures and the second nanostructures in the first plate and the second plate.

42. The method of claim 28, wherein the separator is porous.
